(19) United States
(12) Patent Application Publication
(10) Pub. No.: US 2026/0293106 A1
(43) Pub. Date: Sep. 24, 2026

(54) SEMICONDUCTOR DEVICE AND SEMICONDUCTOR MEMORY DEVICE

(71) Applicant: Kioxia Corporation, Tokyo (JP)

(72) Inventors: Kohei KAWAGUCHI, Yokkaichi Mie (JP); Kenichi HAGA, Yokkaichi Mie (JP); Keiji IKEDA, Yokkaichi Mie (JP); Taiki FUJIMOTO, Yokkaichi Mie (JP)

(21) Appl. No.: 19/331,300

(22) Filed: Sep. 17, 2025

(30) Foreign Application Priority Data
Mar. 21, 2025 (JP) 2025-046970

(51) Int. Cl. H10B 12/00

(52) U.S. Cl. CPC H10B 12/33; H10B 12/05

(57) ABSTRACT

A semiconductor device includes a plurality of oxide semiconductors having respective first ends and respective second ends and extending in a first direction from the second ends to the first ends, a plurality of first electrodes respectively contacting the first ends of the plurality of oxide semiconductors, a plurality of second electrodes respectively contacting the second ends of the plurality of oxide semiconductors, a gate electrode extending in a second direction intersecting the first direction and surrounding each of the plurality of oxide semiconductors that are arranged in the second direction, via a first insulating film between the respective first ends thereof and the respective second ends thereof, and a cavity section at least a portion of which is disposed between two adjacent second electrodes.

### CROSS-REFERENCE TO RELATED APPLICATION(S)

This application is based upon and claims the benefit of priority from Japanese Patent Application No. 2025-046970, filed Mar. 21, 2025, the entire contents of which are incorporated herein by reference.

### FIELD

Embodiments described herein relate generally to a semiconductor device and a semiconductor memory device.

### BACKGROUND

Some semiconductor elements are formed of an oxide semiconductor. In such semiconductor elements, reducing parasitic capacitance between electrodes is desirable.

### BRIEF DESCRIPTION OF THE DRAWINGS

FIG. 1 is a circuit diagram showing an example of a circuit configuration of a memory cell array according to a first embodiment.

FIG. 2 is a schematic cross-sectional view showing an example of a structure of a semiconductor memory device according to the first embodiment.

FIGS. 3-4 are detailed cross-sectional views of the semiconductor device.

FIG. 5 is a cross-sectional view taken along a line V-V shown in FIGS. 3 and 4.

FIG. 6 is a cross-sectional view taken along a line VI-VI shown in FIGS. 3 and 4.

FIGS. 7-8 are cross-sectional views showing a manufacturing process of the semiconductor device according to the first embodiment.

FIG. 9 is a cross-sectional view taken along a line IX-IX shown in FIGS. 7 and 8.

FIG. 10 is a cross-sectional view taken along a line X-X shown in FIGS. 7 and 8.

FIGS. 11-23 are cross-sectional views showing a first manufacturing process of the semiconductor device according to the first embodiment.

FIGS. 24-44 are cross-sectional views showing a second manufacturing process of semiconductor device according to the first embodiment.

FIG. 45 is a detailed cross-sectional view of a semiconductor device according to a second embodiment.

FIG. 46 is a cross-sectional view taken along a line XLVI-XLVI shown in FIG. 45.

FIGS. 47-48 are detailed cross-sectional views of a semiconductor device according to a third embodiment.

FIG. 49 is a cross-sectional view taken along a line XLIX-XLIX shown in FIGS. 47 and 48.

FIGS. 50-51 are detailed cross-sectional views of a semiconductor device according to a fourth embodiment.

FIG. 52 is a cross-sectional view taken along a line LII-LII shown in FIGS. 50 and 51.

FIG. 53 is a detailed cross-sectional view of a semiconductor device according to a fifth embodiment.

FIG. 54 is a cross-sectional view taken along a line LV-LV shown in FIG. 53.

FIG. 55 is a detailed cross-sectional view of a semiconductor device according to a sixth embodiment.

### DETAILED DESCRIPTION

Embodiments provide a semiconductor device and a semiconductor memory device capable of reducing the parasitic capacitance between electrodes.

In general, according to one embodiment, a semiconductor device includes a plurality of oxide semiconductors having respective first ends and respective second ends and extending in a first direction from the second ends to the first ends, a plurality of first electrodes respectively contacting the first ends of the plurality of oxide semiconductors, a plurality of second electrodes respectively contacting the second ends of the plurality of oxide semiconductors, a gate electrode extending in a second direction intersecting the first direction and surrounding each of the plurality of oxide semiconductors that are arranged in the second direction, via a first insulating film between the respective first ends thereof and the respective second ends thereof, and a cavity section at least a part of which is disposed between two adjacent second electrodes.

In general, according to another embodiment, a semiconductor memory device includes the semiconductor device, a first capacitor electrode connected to one of the second electrodes, a second capacitor electrode facing the first capacitor electrode, and a dielectric film disposed between the first capacitor electrode and the second capacitor electrode.

Hereinafter, an embodiment according to the present disclosure will be described with reference to the accompanying drawings. In order to facilitate the understanding of the detailed description, wherever possible, the same components in respective drawings are denoted by the same reference numerals, and duplicate descriptions may be omitted.

### First Embodiment

The configuration of a semiconductor memory device according to a first embodiment will be described. Each drawing may show an X-axis, a Y-axis and a Z-axis. The X-axis, the Y-axis and the Z-axis form a right-handed three-dimensional Cartesian coordinate system. Hereinafter, the direction of the arrow of the X-axis may be referred to as an X-axis positive direction and a direction opposite to the arrow of the X-axis may be referred to as an X-axis negative direction, and the same applies to the other axes. A Z-axis positive direction and a Z-axis negative direction may also be referred to as “an upward direction” and “a downward direction”, respectively. A plane orthogonal to the X-axis, the Y-axis or the Z-axis may be referred to as a YZ plane, a ZX plane or an XY plane. In addition, a Z-axis direction may be referred to as “an upward and downward direction”. The terms “upward direction”, “downward direction” and “upward and downward direction” are merely terms that indicate relative positional relationships in the drawings, and are not terms that define directions on the basis of a vertical direction.

Unless otherwise specifically described, the dimensions of components shown in each drawing may be shown differently from their actual dimensions in order to facilitate the understanding of description.

In the present specification, the term “connection” includes not only a physical connection but also an electrical connection, and, unless otherwise specifically pointed out, includes not only a direct connection but also an indirect connection.

In the present specification, the term “being formed over” includes not only a case of “being formed in contact with” but also, unless otherwise specifically pointed out, a case of “being formed via another object”. The same is true for a case such as “being formed under”.

A semiconductor memory device 101 according to the first embodiment is a DRAM (dynamic random access memory) provided with vertical memory transistors and includes a memory cell array.

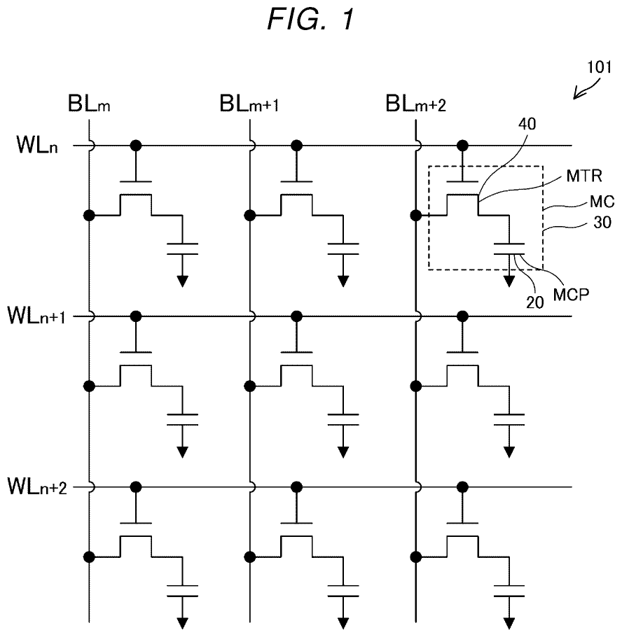

As shown in FIG. 1, the memory cell array includes a plurality of memory cells MC, a plurality of word lines WL, and a plurality of bit lines BL.

FIG. 1 shows a word line WLₙ, a word line WLₙ₊₁ and a word line WLₙ₊₂ (where n is a positive integer) as an example of the plurality of word lines WL. In addition, FIG. 1 shows a bit line BLₘ, a bit line BLₘ₊₁ and a bit line BLₘ₊₂ (where m is a positive integer) as an example of the plurality of bit lines BL. The number of the plurality of memory cells MC is not limited to the number shown in FIG. 1.

The plurality of memory cells MC are arranged, for example, in a matrix configuration, to form the memory cell array. The memory cell MC includes a memory transistor MTR, which is a field effect transistor (FET), and a memory capacitor MCP.

A series of memory cells MC that are disposed in a row direction are connected to a word line WL (e.g., the word line WLₙ) corresponding to a row (e.g., an nth row) to which the series of memory cells MC belong. A series of memory cells MC that are disposed in a column direction are connected to a bit line BL (e.g., the bit line BLₘ₊₂) corresponding to a column (e.g., an (m+2)th column) to which the series of memory cells MC belong.

In detail, the gate of the memory transistor MTR in the memory cell MC is connected to a word line WL corresponding to a row to which the memory cell MC belongs. One of the source and the drain of the memory transistor MTR is connected to a bit line BL corresponding to a column to which the memory cell MC belongs.

One electrode of the memory capacitor MCP in the memory cell MC is connected to the other of the source and the drain of the memory transistor MTR in the memory cell MC. The other electrode of the memory cell MC is connected to a power supply line (not shown) that supplies specific potential.

The memory cell MC is configured to be able to store data by accumulating charge in the memory capacitor MCP by a current flowing through the corresponding bit line BL, by switching of the memory transistor MTR on the basis of the potential of the corresponding word line WL.

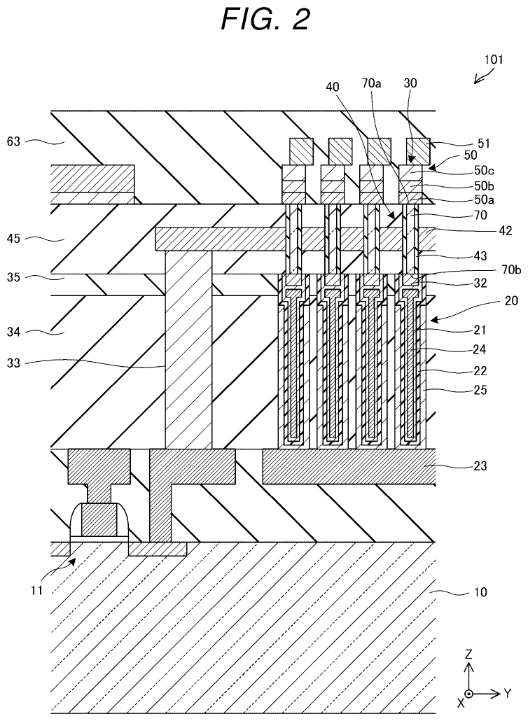

As shown in FIG. 2, the semiconductor memory device 101 includes a semiconductor substrate 10, a circuit 11 (an example of a “semiconductor circuit”), a capacitor 20, a semiconductor device 30, a conductor 33, and insulating layers 34, 35 and 63.

The capacitor 20 includes an insulating film 22 (an example of a “dielectric film”), a conductor 23, a capacitor electrode 24 (an example of a “first capacitor electrode”), and a capacitor electrode 25 (an example of a “second capacitor electrode”).

The semiconductor device 30 includes a plurality of field effect transistors 40 (an example of “semiconductor elements”), a plurality of upper electrodes 50 (an example of “first electrodes”) disposed over the field effect transistors 40, a plurality of lower electrodes 32 (an example of “second electrodes”) disposed under the field effect transistors 40, and a plurality of conductive layers 51 (an example of “bit electrodes”).

The field effect transistor 40 includes an oxide semiconductor layer 70 (an example of an “oxide semiconductor”), a gate insulating film 43 (an example of a “first insulating film”), a conductive layer 42 (an example of a “gate electrode”), and an insulating layer 45. The field effect transistor 40 corresponds to the memory transistor MTR of the memory cell MC (see FIG. 1).

The oxide semiconductor layer 70 is formed in the insulating layer 45 and has an upper end 70a (an example of a “first end”) and a lower end 70b (an example of a “second end”). The oxide semiconductor layer 70 is a columnar body that extends in the Z-axis positive direction (an example of a “first direction”) from the lower end 70b to the upper end 70a. The oxide semiconductor layer 70 forms the channel of the field effect transistor 40. The oxide semiconductor layer 70 has an amorphous structure.

The oxide semiconductor layer 70 is a semiconductor in which oxygen vacancies act as donor sites. The oxide semiconductor layer 70 includes at least one of indium (In), gallium (Ga), aluminum (Al), zinc (Zn), tin (Sn), titanium (Ti), tungsten (W), molybdenum (Mo), iridium (Ir) and ruthenium (Ru), and oxygen. Additionally, the oxide semiconductor layer 70 may be formed from a type of channel material other than an oxide semiconductor. For example, it may be constituted by a material containing any of single-crystal silicon (c-Si), polycrystalline silicon (poly-Si), amorphous silicon (a-Si), impurity-doped silicon, silicon germanium (SiGe), or germanium (Ge).

In the present embodiment, the oxide semiconductor layer 70 includes indium, zinc and gallium as metal elements. In detail, the oxide semiconductor layer 70 is an oxide of indium, gallium and zinc, that is, IGZO (InGaZnO). The oxide semiconductor layer 70 may be another type of oxide semiconductor.

The field effect transistor 40 is a so-called vertical transistor that has a channel extending in the Z-axis direction (the upward and downward direction) substantially perpendicular to the surface of the semiconductor substrate 10.

The upper electrode 50 is formed on the oxide semiconductor layer 70. The plurality of upper electrodes 50 are in contact with the upper ends 70a of a plurality of oxide semiconductor layers 70, respectively.

The conductive layer 51 is connected to the upper end 70a of the oxide semiconductor layer 70 through the upper electrode 50. The conductive layer 51 includes, for example, tungsten (W).

The conductive layer 51 extends in the X-axis direction over the conductive layer 42. The plurality of conductive layers 51 are disposed. The plurality of conductive layers 51 are repeatedly disposed in the Y-axis direction. The plurality of conductive layers 51 are spaced apart from each other in the Y-axis direction. The conductive layer 51 corresponds to a bit line BL (see FIG. 1). In the present embodiment, the width of the conductive layer 51 in the Y-axis direction is approximately constant.

The lower electrode 32 is formed under the oxide semiconductor layer 70. The plurality of lower electrodes 32 are in contact with the lower ends 70b of the plurality of oxide semiconductor layers 70, respectively. The lower electrode 32 includes a conductive oxide. In detail, the lower electrode 32 is formed of metal oxide including, for example, indium and tin as metal elements. In the present embodiment, the lower electrode 32 is formed of indium-tin-oxide (ITO).

The circuit 11 includes a peripheral circuit such as a decoder for selecting a specific memory cell MC among the plurality of memory cells MC, that is, the capacitors 20 and the field effect transistors 40, of the semiconductor memory device 101, a sense amplifier connected to the bit line BL, and a register implemented using SRAM. The circuit 11 may include a CMOS circuit that has a field effect transistor such as a P-channel type field effect transistor (Pch-FET) and an N-channel type field effect transistor (Nch-FET) formed by a CMOS process.

The field effect transistor of the circuit 11 may be formed using the semiconductor substrate 10 such as a monocrystalline silicon substrate. The Pch-FET and the Nch-FET are so-called lateral field effect transistors each of which has a channel region, a source region and a drain region in the semiconductor substrate 10 and has a channel for carrier flow in the X-axis direction or the Y-axis direction substantially parallel to the surface of the semiconductor substrate 10 in a region close to the surface of the semiconductor substrate 10. The semiconductor substrate 10 may have a P-type or N-type conductivity. For convenience, FIG. 2 illustrates an example of the field effect transistor of the circuit 11.

The capacitor 20 is the memory capacitor MCP in the memory cell MC (see FIG. 1). Although FIG. 2 illustrates four capacitors 20, the number of capacitors 20 is not limited to four.

In the present embodiment, the capacitor 20 is disposed over the semiconductor substrate 10. The capacitor electrode 24 of the capacitor 20 is disposed under the lower electrode 32. The capacitor electrode 24 is connected to the lower electrode 32 through a conductor 21.

The capacitor electrode 25 faces the capacitor electrode 24. The insulating film 22 is disposed between the capacitor electrode 24 and the capacitor electrode 25.

The capacitor 20 is a three-dimensional capacitor such as a pillar-type capacitor. As the capacitor of the present embodiment, other capacitors capable of storing electric charge may be used.

In detail, the capacitor electrode 24 is located below the lower electrode 32. The capacitor electrode 24 has an upper end that faces the lower end surface of the lower electrode 32 via the conductor 21, and has a columnar shape that extends downward from the upper end. The conductor 21 is formed to cover the lower electrode 32 and the capacitor electrode 24.

The insulating film 22 is formed to cover the conductor 21. The capacitor electrode 25 surrounds a lower part of the insulating film 22, and has a lower end that abuts against the upper end surface of the conductor 23. The upper end of the capacitor electrode 25 is located lower than the upper end of the lower electrode 32. In other words, between two adjacent (neighboring) lower electrodes 32, except the conductor 21 that covers the lower electrodes 32, a portion that is not shielded by a conductor is formed.

The capacitor electrodes 24 may include silicon, germanium, and the like. In detail, the capacitor electrode 24 may include SiGe.

The insulating film 22 has a high dielectric constant. In the present embodiment, the insulating film 22 may include zirconium, aluminum and oxygen. In detail, the insulating film 22 may include ZAZ, which is an alternate stacked film of Zr—O and Al—O. The insulating film 22 is not limited to the composition including ZAZ, but may have a composition including at least one of Hf—Zr—O (HZO), Zr—Nb—O (ZNO) and Hf—Al—O (HAO).

The conductor 21 is, for example, a barrier metal. The conductor 21 may include materials such as tungsten or titanium nitride, and may also include materials such as amorphous silicon. Additionally, it may include metal oxides such as InO, ITO, or RuO. The conductor 23 and the capacitor electrode 25 may include tungsten, titanium nitride, and the like.

The conductor 33 includes a wiring that electrically connects the circuit 11 and the semiconductor device 30. The conductor 33 may include a via wiring. For example, the conductor 33 has a via wiring that extends in the Z-axis direction as shown in FIG. 2 and connects the conductive layer 42 functioning as a word line WL and the circuit 11 disposed on the semiconductor substrate 10. The conductor 33 includes, for example, copper.

The insulating layer 34 is disposed between the plurality of capacitors 20. The insulating layer 34 is, for example, a silicon oxide film including silicon and oxygen.

The insulating layer 35 is disposed over the insulating layer 34. The insulating layer 35 is, for example, a silicon nitride film including silicon and nitrogen.

An axis that intersects the Z-axis perpendicularly and intersects the X-axis at an angle of 30 degrees counterclockwise when viewed from the top is defined as an A-axis. A plane parallel to the Z-axis and the A-axis may be referred to as a ZA plane. Moreover, an axis that intersects the Z-axis perpendicularly and intersects the X-axis at an angle of 30 degrees clockwise when viewed from the top is defined as a B-axis.

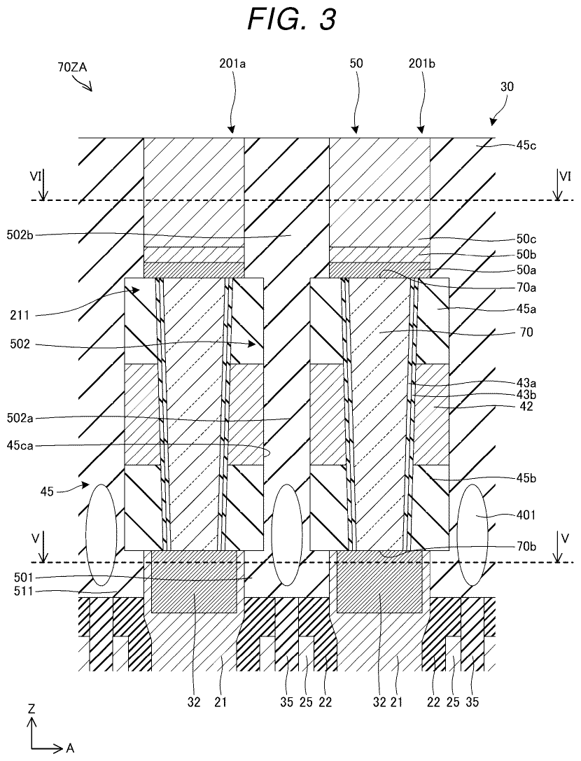

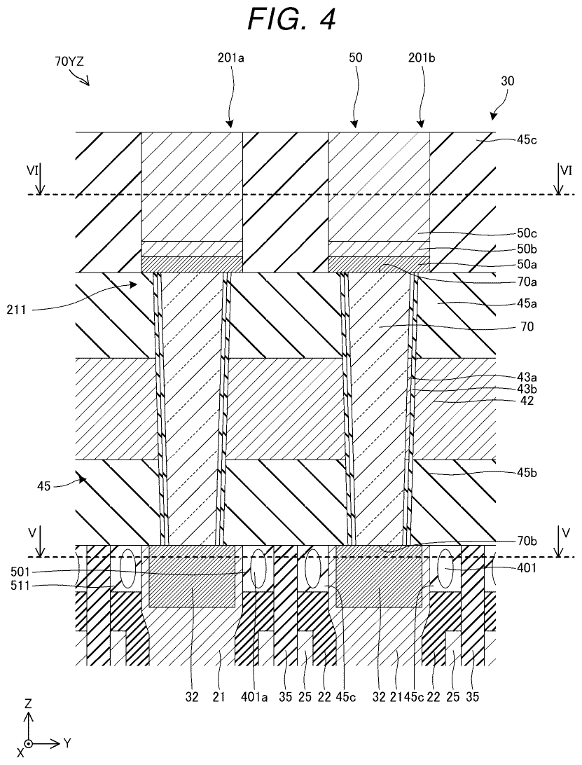

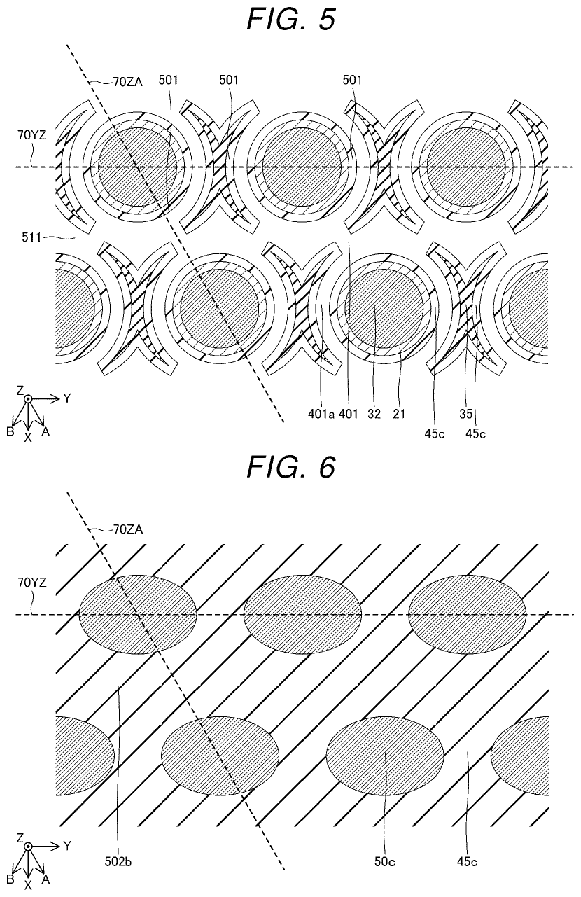

FIG. 3 is a detailed cross-sectional view of the semiconductor device 30 as viewed in a cross-section 70ZA parallel to the ZA plane and included in the oxide semiconductor layer 70. FIG. 4 is a detailed cross-sectional view of the semiconductor device 30 as viewed in a cross-section 70YZ parallel to the YZ plane and included in the oxide semiconductor layer 70. FIG. 5 is a cross-sectional view taken along a line V-V shown in FIGS. 3 and 4. FIG. 6 is a cross-sectional view taken along a line VI-VI shown in FIGS. 3 and 4.

As shown in FIGS. 3 to 6, in the present embodiment, the upper electrode 50 has a columnar shape that extends in the Z-axis positive direction from the upper end 70a of the oxide semiconductor layer 70 in contact with the upper electrode 50. In detail, the upper electrode 50 has a constant cross-section and an axis that is substantially parallel to the Z-axis. The cross-section of the upper electrode 50 has an oval shape that has a major axis substantially parallel to the Y-axis.

The upper electrode 50 may be configured to have a taper shape that narrows upward or downward. The cross-section of the upper electrode 50 is not limited to an oval shape and may have a circular shape.

The lower electrode 32 has a columnar shape that extends in a direction opposite to the Z-axis positive direction from the lower end 70b of the oxide semiconductor layer 70 in contact with the lower electrode 32. In detail, the lower electrode 32 has a circular columnar shape that has an axis substantially parallel to the Z-axis. The side surface and the bottom surface of the lower electrode 32 are covered by the conductor 21.

The lower electrode 32 is not limited to the configuration that has a circular columnar shape, and may be configured to have a taper shape that narrows upward or downward. The cross-section of the lower electrode 32 is not limited to a circular shape and may have an oval shape.

The gate insulating film 43 surrounds the side surface of the oxide semiconductor layer 70. In the present embodiment, the gate insulating film 43 includes insulating films 43a and 43b.

In detail, the insulating film 43b includes, for example, silicon and nitrogen. In detail, the insulating film 43b includes, for example, a silicon nitride film (Si₃N₄). The insulating film 43a includes, for example, silicon and oxygen. In detail, the insulating film 43a includes a silicon oxide film (SiO₂). The insulating film 43a is disposed between the insulating film 43b and the oxide semiconductor layer 70, and is formed to cover the entire circumference of the side surface of the oxide semiconductor layer 70.

The gate insulating film 43 is not limited to the configuration that includes two insulating films, and may have a configuration that includes a single insulating film or three or more insulating films. The gate insulating film 43 is not limited to a silicon nitride film or a silicon oxide film, but may be a high-k insulating film that has a large dielectric constant (for example, an insulating film including Hf—O, Al—O, Hf—Al—O, Zr—O, Hf—Zr—O or Zr—Nb—O) or a mixture thereof (HfZrO₂, HfAlO, ZrAlO), or a laminate thereof.

A columnar body 201 is described next. The columnar body 201 includes the oxide semiconductor layer 70, the gate insulating film 43 that surrounds the oxide semiconductor layer 70, and the lower electrode 32 and the upper electrode 50 in contact with the oxide semiconductor layer 70. The columnar body 201 has a columnar shape that extends as a whole in the upward and downward direction. Columnar bodies 201a and 201b are examples of the columnar body 201.

Hereinafter, a set including the oxide semiconductor layer 70 and the upper electrode 50 in the columnar body 201 may be referred to as a column set 211.

A plurality of columnar bodies 201 are arranged side by side in a third direction that intersects the Z-axis positive direction and the Y-axis positive direction, for example, an A-axis positive direction or a B-axis positive direction. In detail, one columnar body 201 among the plurality of columnar bodies 201 is surrounded by six columnar bodies 201 located closest thereto when viewed from the top.

In more detail, when viewed from the top, one oxide semiconductor layer 70 provided in the corresponding one columnar body 201 is located at the center of a regular hexagon, and six oxide semiconductor layers 70 provided in the six columnar bodies 201, respectively, are located at the vertices of the regular hexagon. In other words, the columnar bodies 201 are disposed in a hexagonally close-packed manner.

The plurality of oxide semiconductor layers 70 are repeatedly disposed at regular intervals substantially parallel to each other in the Y-axis positive direction. Furthermore, the plurality of oxide semiconductor layers 70 are repeatedly disposed at the corresponding regular intervals in the A-axis positive direction or the B-axis positive direction. The plurality of oxide semiconductor layers 70 may deviate in direction or interval within the degree of manufacturing error.

The conductive layer 42 extends in a second direction that intersects the Z-axis positive direction, for example, the Y-axis positive direction. The conductive layer 42 surrounds the oxide semiconductor layers 70 via the gate insulating film 43 between the upper end 70a and the lower end 70b of each of the plurality of oxide semiconductor layers 70 disposed in the Y-axis direction.

In detail, the oxide semiconductor layer 70 and the gate insulating film 43 penetrate the conductive layer 42. Above and below the conductive layer 42, the oxide semiconductor layer 70 and the gate insulating film 43 protrude. Namely, the conductive layer 42 surrounds the plurality of oxide semiconductor layers 70 between the upper ends 70a and the lower ends 70b of the respective oxide semiconductor layers 70 of the plurality of oxide semiconductor layers 70 disposed in the Y-axis direction, via a plurality of gate insulating films 43, respectively.

The conductive layer 42 functions as the gate electrode of the field effect transistor 40. The conductive layer 42 includes, for example, tungsten (W). The conductive layer 42 is not limited to the composition including tungsten, and may have a composition including molybdenum (Mo), titanium nitride (TiN), cobalt (Co) or ruthenium (Ru).

A plurality of conductive layers 42 are disposed. The plurality of conductive layers 42 are repeatedly disposed in the X-axis direction. The plurality of conductive layers 42 are spaced apart from each other in the X-axis direction. The insulating layer 45 is disposed over and under the conductive layer 42 and between two conductive layers 42 in the X-axis direction. That is to say, two adjacent conductive layers 42 in the X-axis direction are separated by a part of the insulating layer 45. The insulating layer 45 includes, for example, silicon and oxygen. The conductive layer 42 corresponds to a word line WL (see FIG. 1).

In the present embodiment, the upper electrode 50 includes a metal oxide layer 50a, a barrier metal layer 50b and a metal film 50c.

The metal oxide layer 50a of the upper electrode 50 includes conductive oxide. In detail, the metal oxide layer 50a is metal oxide that includes indium and tin as metal elements. In more detail, the metal oxide layer 50a is formed of indium-tin-oxide (ITO). The metal oxide layer 50a is disposed over the oxide semiconductor layer 70. The metal oxide layer 50a has a thin film shape that extends along a plane parallel to the XY plane.

The lower electrode 32 and the metal oxide layer 50a are not limited to ITO, and may have a composition including at least any one element among indium, tin, zinc, cadmium, gold, silver, platinum, lead, copper, nickel, tungsten and iron.

In detail, the lower electrode 32 and the metal oxide layer 50a may have a composition including at least any one among In—Sn—O—N (ITON), In—Ga—O (IGO), Al—Zn—O (AZO), Ga—Zn—O (GZO), Sn—O, Sn—Nb—O, Sn—Ta—O, Sn—O—F (FTO), Ti—O, Ti—Nb—O (TNO), Ti—W—O, Mo—O and W—O.

The barrier metal layer 50b is stacked on the metal oxide layer 50a. In the present embodiment, the barrier metal layer 50b has a thin film shape that extends along a plane parallel to the XY plane.

The barrier metal layer 50b includes titanium, oxygen and nitrogen. In detail, the barrier metal layer 50b has a stacked structure of titanium oxide (TiO) and titanium nitride (TiN).

The barrier metal layer 50b may be formed of Ti—O—N (TiON). The barrier metal layer 50b may also have a composition including titanium, and one of oxygen and nitrogen. The barrier metal layer 50b may also have a composition further including a metal element other than titanium. In detail, the barrier metal layer 50b may also have a composition further including, for example, tungsten.

The metal film 50c is stacked on the metal oxide layer 50a. In the present embodiment, the metal film 50c has a thin film shape that extends along a plane parallel to the XY plane. The metal film 50c includes, for example, tungsten.

In the present embodiment, the insulating layer 45 has a thin film shape that extends along a plane parallel to the XY plane. The conductive layer 42 is formed in the insulating layer 45. The columnar body 201 penetrates the insulating layer 45.

In detail, the insulating layer 45 includes insulating films 45a, 45b and 45c (an example of a “second insulating film”). The insulating films 45a and 45b are disposed over and under the conductive layer 42, respectively, and are in contact with the conductive layer 42. The insulating films 45a and 45b extend in the Y-axis positive direction together with the conductive layer 42. The insulating films 45a and 45b together with the conductive layer 42 surround the oxide semiconductor layer 70 and the gate insulating film 43.

The insulating film 45c includes an insulating section 501 (an example of a “first section”) and an insulating section 502 (an example of a “second section”).

The insulating section 502 is located between two column sets 211 that are adjacent to each other in the A-axis positive direction or the B-axis positive direction. In the present embodiment, the insulating section 502 includes insulating sections 502a and 502b.

The insulating section 502b is disposed over the insulating film 45a, and surrounds the side surfaces of the plurality of upper electrodes 50. In other words, the upper electrode 50 penetrates the insulating section 502a in the upward and downward direction. The upper surfaces of the metal films 50c in the plurality of upper electrodes 50 are exposed from the upper surface of the insulating section 502b.

The insulating section 502a is continuous with the insulating section 502b, and fills the space between the insulating films 45a and 45b and the conductive layers 42 that are adjacent to each other in the X-axis direction.

The insulating section 501 is disposed under the insulating film 45b. The insulating section 501 is continuous with the insulating section 502. The insulating section 501 is disposed at a layer 511 that includes the plurality of lower electrodes 32. The layer 511 is disposed between the insulating film 45b and the insulating film 22.

Under the insulating film 45b, the lower electrode 32, the side surface of which is covered with the conductor 21, and the insulating layer 35 penetrate the layer 511 in the upward and downward direction.

At least a part of a cavity section 401 is disposed between two adjacent lower electrodes 32. In the present embodiment, the cavity section 401 extends between two column sets 211 that are adjacent to each other in the A-axis positive direction or the B-axis positive direction. The cavity section 401 spreads between two column sets 211 that are adjacent to each other in the A-axis positive direction or the B-axis positive direction. Namely, the cavity section 401 extends between two adjacent lower electrodes 32 and between two column sets 211 adjacent to each other in the A-axis positive direction or the B-axis positive direction.

At least a part of the cavity section 401 is surrounded by the insulating section 501. In detail, between two lower electrodes 32 that are adjacent to each other in the Y-axis positive direction, the cavity section 401 forms a tunnel 401a with the insulating section 501 as an inner wall.

The cavity section 401 extends from the insulating section 501 to the insulating section 502. The cavity section 401 surrounds the side surface of the lower electrode 32.

In detail, in the layer 511, the insulating layer 35 is disposed between two lower electrodes 32 that are adjacent to each other in the Y-axis positive direction. The side surface of the insulating layer 35 is surrounded by the insulating section 501. The side surface of the conductor 21 is surrounded by the insulating section 501.

Portions where the insulating layer 35 is not disposed are present between two lower electrodes 32 adjacent to each other in the A-axis positive direction and between two lower electrodes 32 adjacent to each other in the B-axis positive direction.

The tunnel 401a is disposed in a circumferential direction with the axis of the lower electrode 32 (the oxide semiconductor layer 70) as a center axis. The insulating section 501 that surrounds the insulating layer 35 and the insulating section 501 that surrounds the conductor 21 form the outside inner wall and the inside inner wall, respectively, of the tunnel 401a.

Between two column sets 211 that are adjacent to each other in the A-axis positive direction or the B-axis positive direction, the cavity section 401 is disposed under the insulating section 502a. The cavity section 401 in the insulating section 502a and the cavity section 401 in the insulating section 501 are continuous with each other.

### Effects

For example, when a dielectric is filled between two adjacent lower electrodes 32, the parasitic capacitance between the two lower electrodes 32 increases. In particular, when the insulating film 22 with a large dielectric constant is disposed between two lower electrodes 32 or when the lower electrodes 32 are hexagonally close-packed and the distance between the two lower electrodes 32 is short, the parasitic capacitance significantly increases.

When the parasitic capacitance is large, it takes a long time to charge the parasitic capacitance and the operation of the semiconductor device 30 slows down, which are not preferable.

As described above, by the configuration in which at least a part of the cavity section 401 is provided in the insulating section 501, it is possible to arrange the cavity section 401 with a small dielectric constant between two lower electrodes 32, whereby it is possible to reduce the parasitic capacitance between the two lower electrodes 32. Accordingly, because it is possible to shorten a time required to charge parasitic capacitance, it is possible to speed up the operation of the semiconductor device 30 and thus the operation of the OCTRAM.

Furthermore, by the configuration in which the cavity section 401 surrounds the side surface of the lower electrode 32, the lower electrode 32 may be supplied with oxygen from all directions through the cavity section 401.

### First Manufacturing Method of a Semiconductor Device 30

A first manufacturing method of the semiconductor device 30 will be described hereunder as an example of a method for manufacturing a semiconductor device according to the first embodiment. In the first manufacturing method, the conductive layer 42 is formed in a self-aligned manner around the oxide semiconductor layer 70 and the gate insulating film 43.

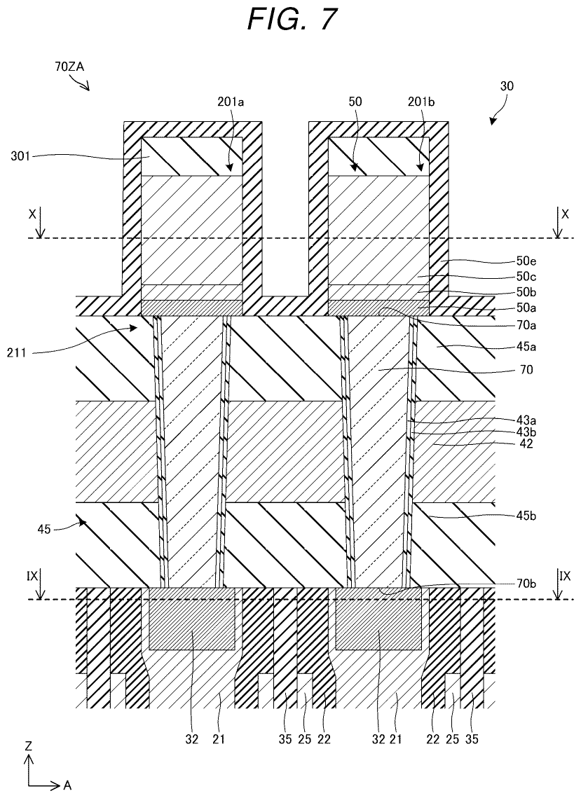

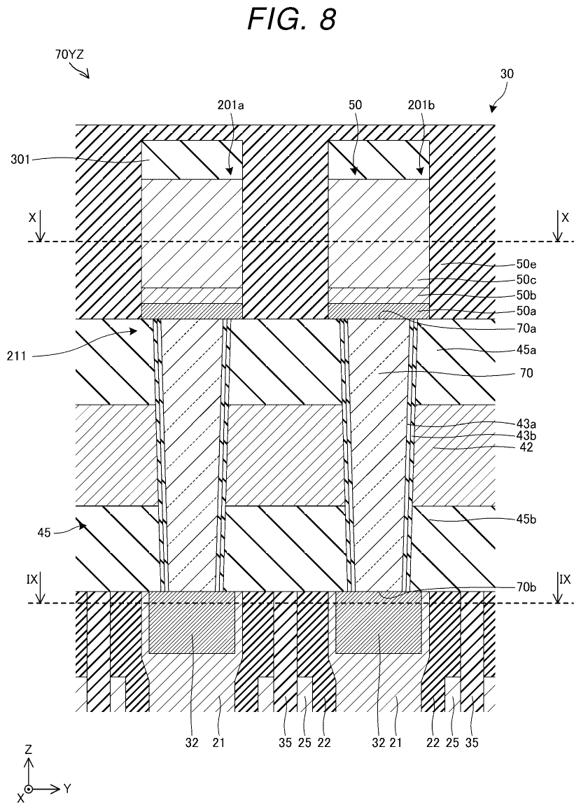

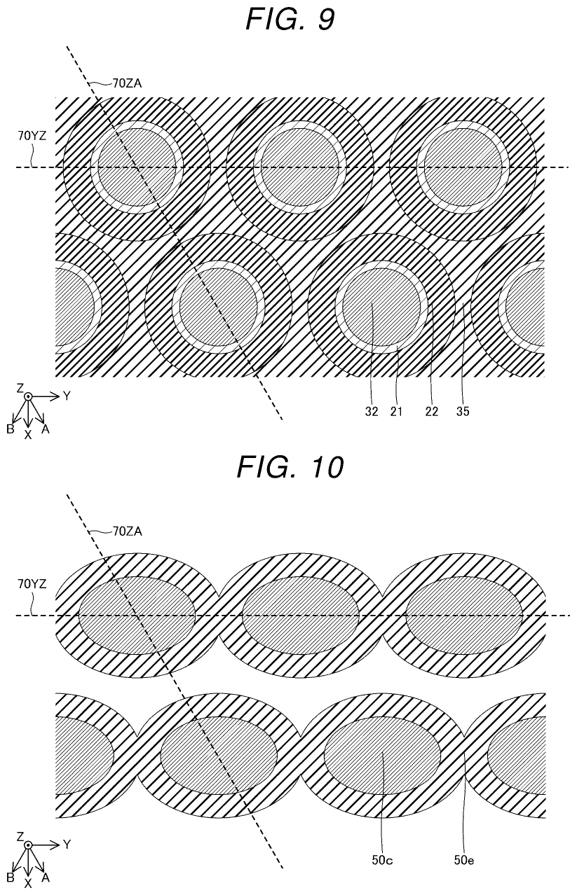

First, as shown in FIGS. 7 to 10, for example, an insulating film 301 is stacked on the upper surface of the upper electrode 50. The insulating film 301 functions as, for example, a hard mask for the upper electrode 50. In a state in which columnar bodies 201 that penetrate the insulating layer 45 and the conductive layer 42 are formed, a spacer film 50e is formed on the side surface of the upper electrode 50, the upper surface of the insulating film 301 and the upper surface of the insulating film 45a by atomic layer deposition.

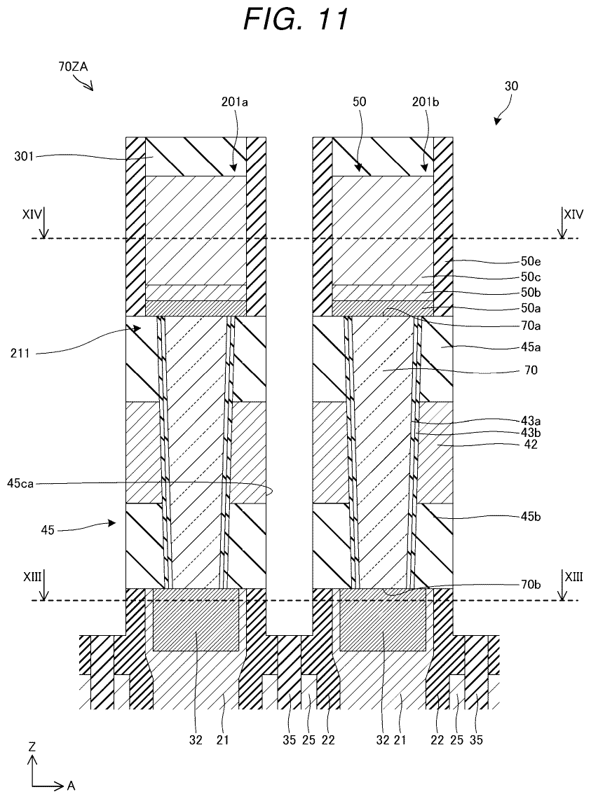

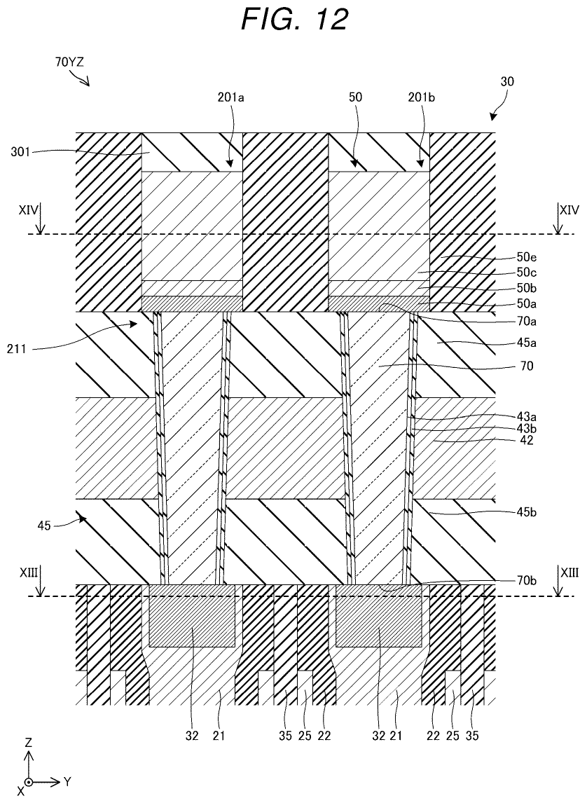

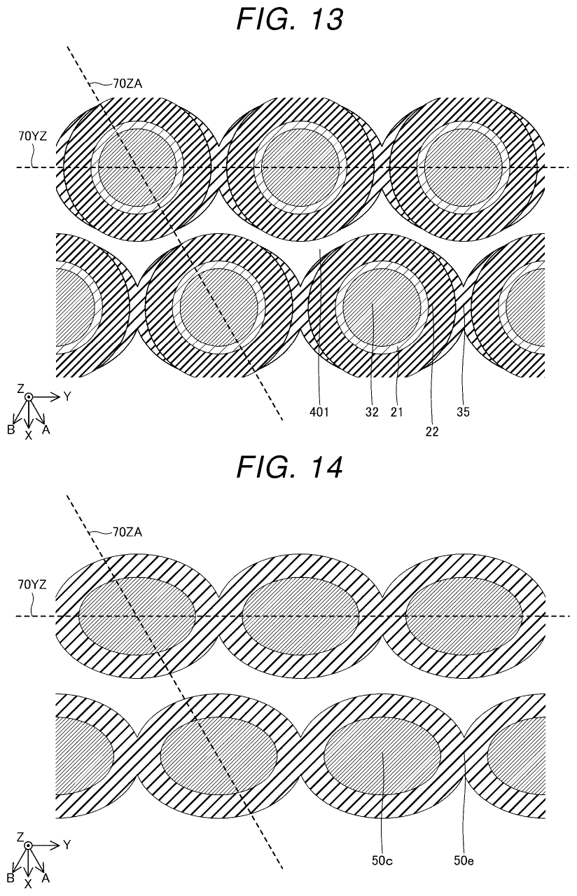

Next, as shown in FIGS. 11 to 14, a groove section 45ca is formed by reactive ion etching, and then, cleaning is performed. The groove section 45ca extends substantially parallel to the XY plane, and divides the conductive layer 42 and the insulating layer 45. In the vicinity of the bottom of the groove section 45ca, an insulating layer 35 and the insulating film 22 are exposed. The sidewall of the groove section 45ca forms an unevenness along the outer contour of the spacer film 50e when viewed from the top.

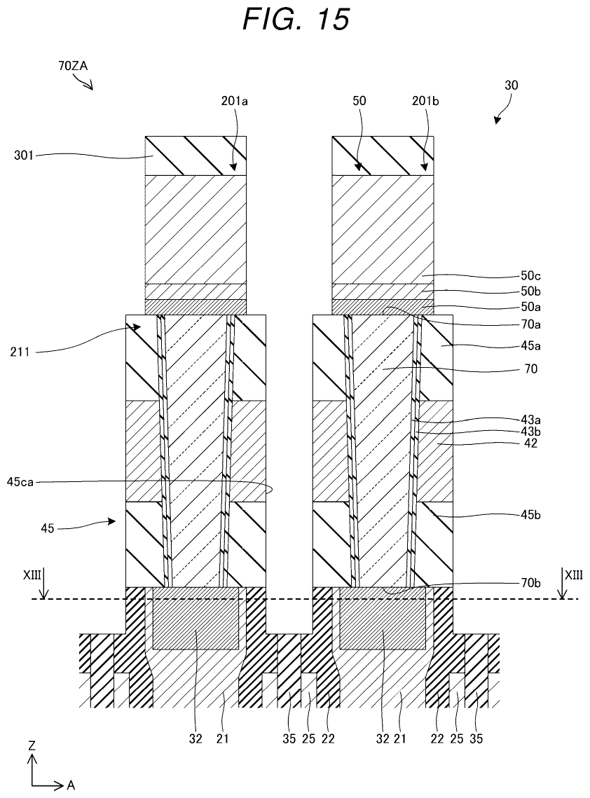

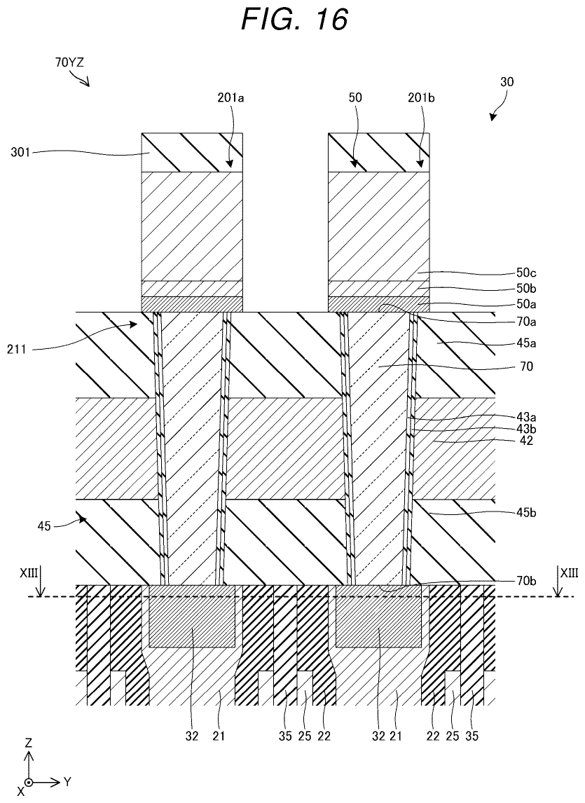

Next, as shown in FIGS. 15 and 16, the spacer film 50e is removed by reactive ion etching, and then, cleaning is performed.

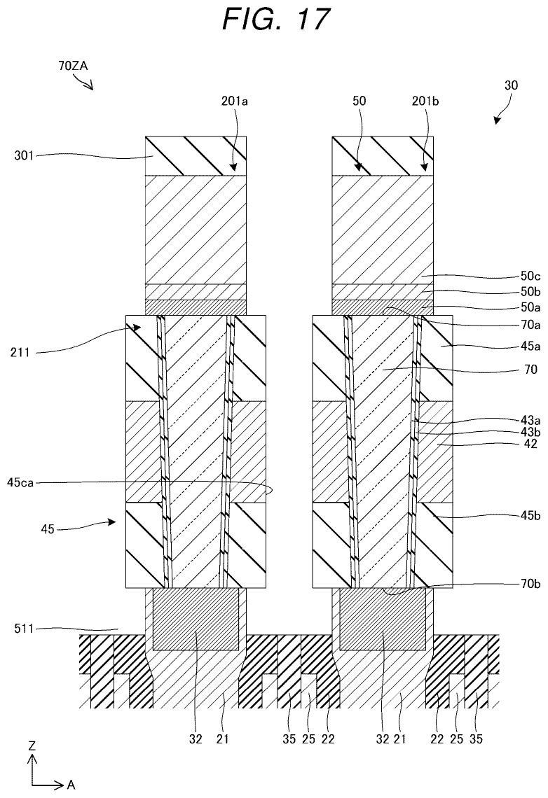

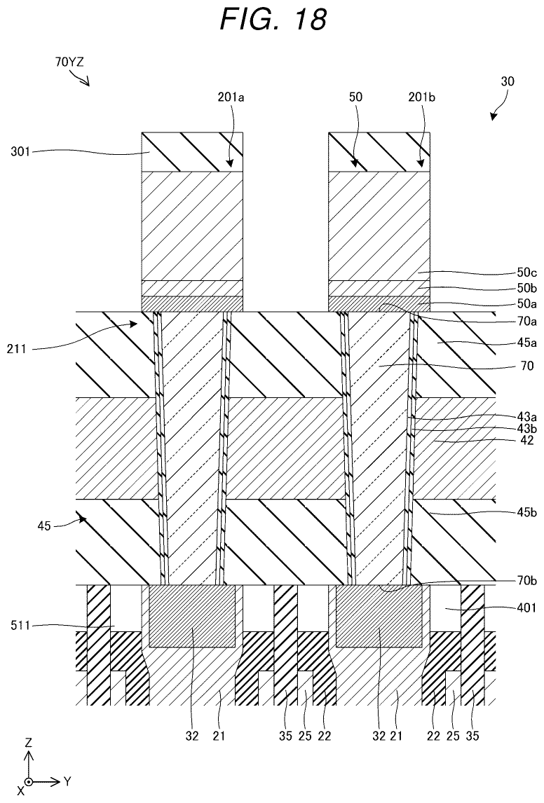

Next, as shown in FIGS. 17 and 18, a part of the insulating film 22 is removed by, for example, wet etching. By this fact, at the layer 511, the conductor 21 is exposed to the cavity section 401. The cavity section 401 surrounds the conductor 21.

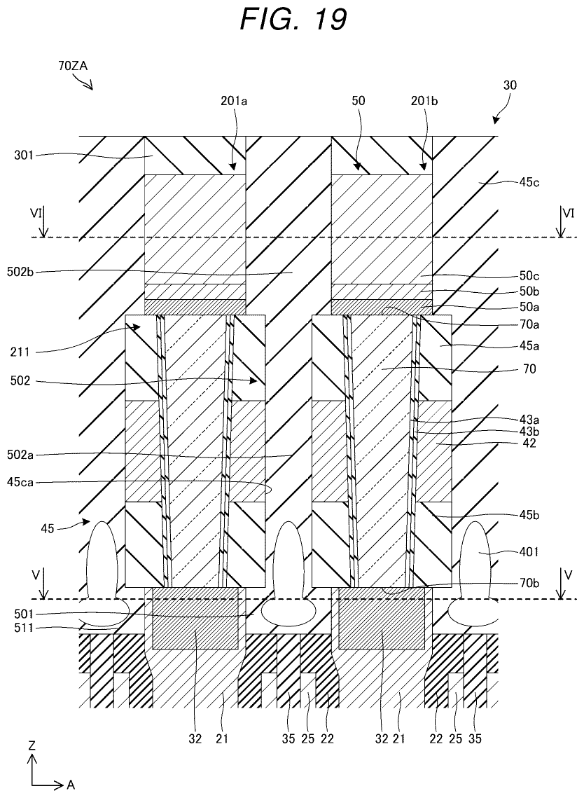

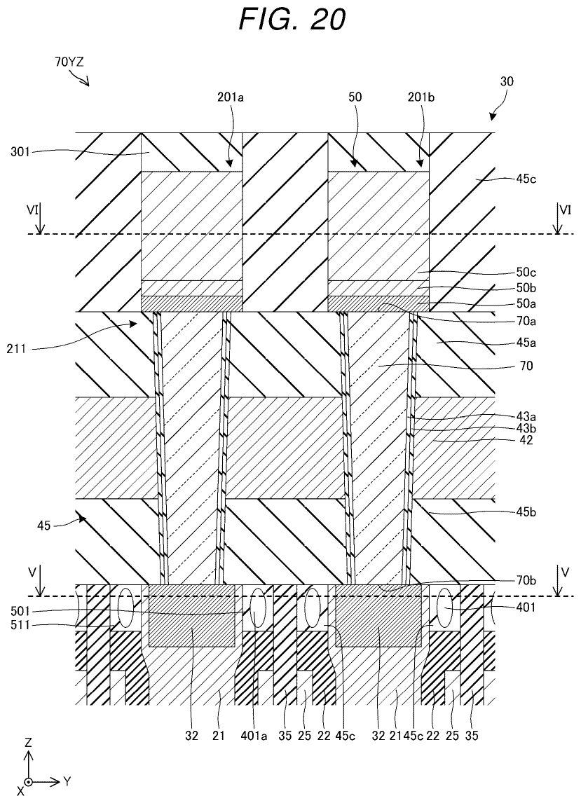

Next, as shown in FIGS. 19 and 20, the insulating film 45c is formed by, for example, atomic layer deposition. The cavity section 401 is formed according to the degree of ease with which the insulating film 45c can be embedded. The degree of ease with which the insulating film 45c can be embedded, may be adjusted according to, for example, process conditions when forming the insulating film 45c. For example, by increasing the degree of ease with which the insulating film 45c can be embedded, the volume of the cavity section 401 may be made smaller. Also, for example, by decreasing the degree of ease with which the insulating film 45c can be embedded, the volume of the cavity section 401 may be increased.

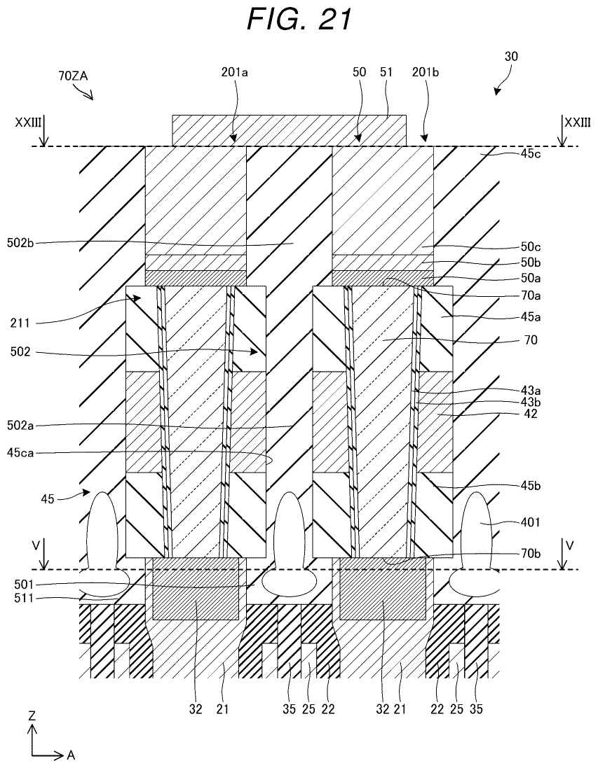

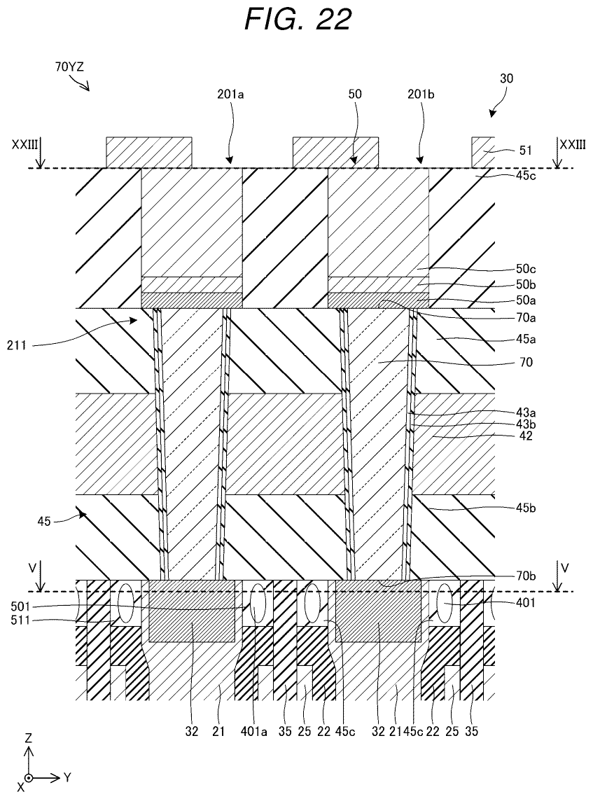

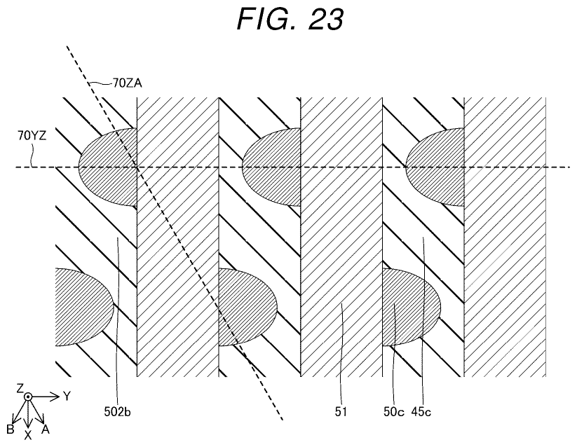

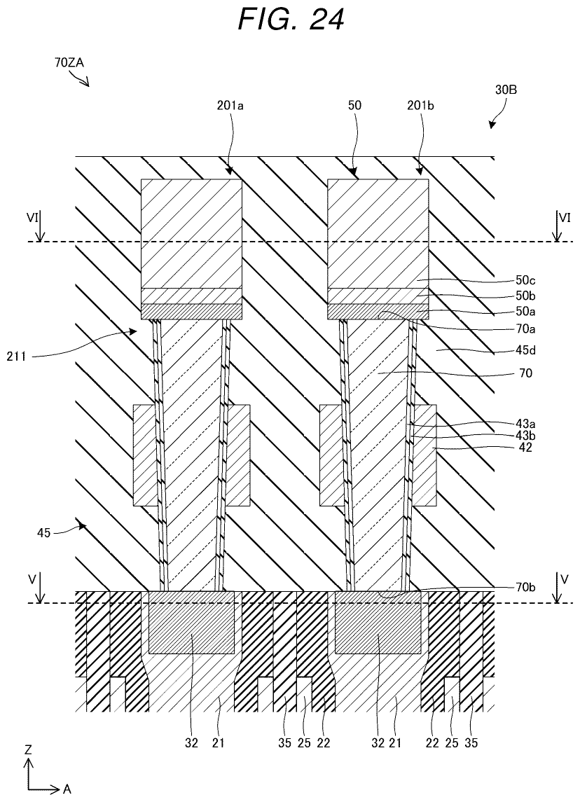

Next, as shown in FIGS. 21 to 23, as upper parts of the insulating film 301 and the insulating film 45c are removed by chemical mechanical polishing, the upper surface of the metal film 50c in the upper electrode 50 is exposed from the insulating film 45c, and the locations of the upper surface of the insulating film 45c and the upper surface of the metal film 50c in the upward and downward direction are flush with each other. On a surface smoothed in this manner, a conductive layer 51 that extends in the X-axis positive direction and comes into contact with the metal film 50c is formed.

### Second Manufacturing Method of a Semiconductor Device 30b

A second manufacturing method of the semiconductor device 30B will be described hereunder as another example of the method for manufacturing a semiconductor device according to the first embodiment. The second manufacturing method differs from the first manufacturing method in that the sidewall of the groove section 45ca is formed to be smooth.

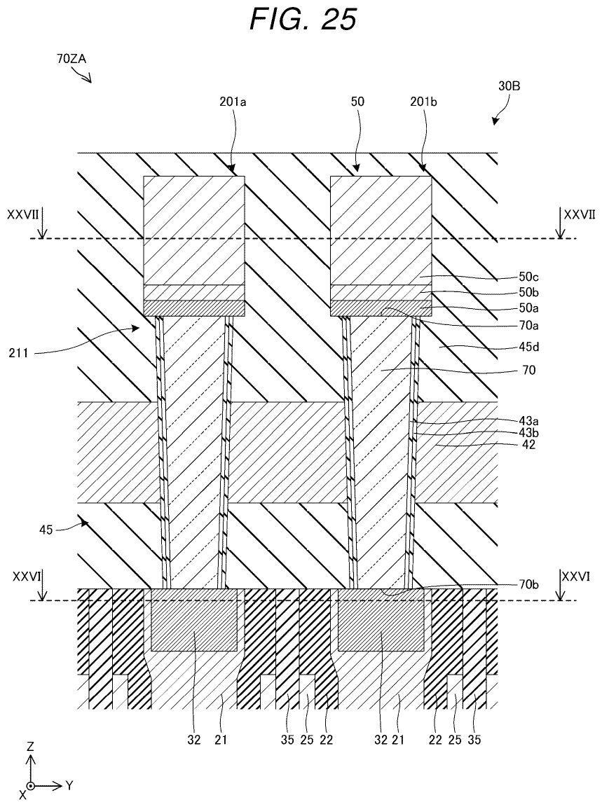

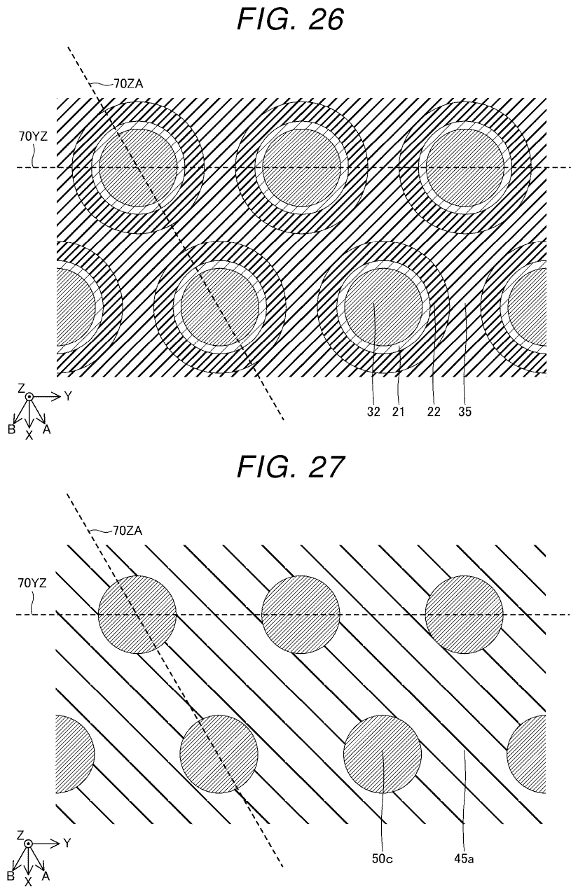

First, as shown in FIGS. 24 to 27, compared to the insulating layer 45 of the semiconductor device 30, the insulating layer 45 of the semiconductor device 30B includes the insulating film 45d instead of the insulating films 45a and 45b. For example, the columnar body 201 is embedded in an insulating film 45d. A plurality of conductive layers 42 are repeatedly disposed in the X-axis positive direction. Each conductive layer 42 extends in the Y-axis positive direction. The cross-section of the upper electrode 50 is substantially circular.

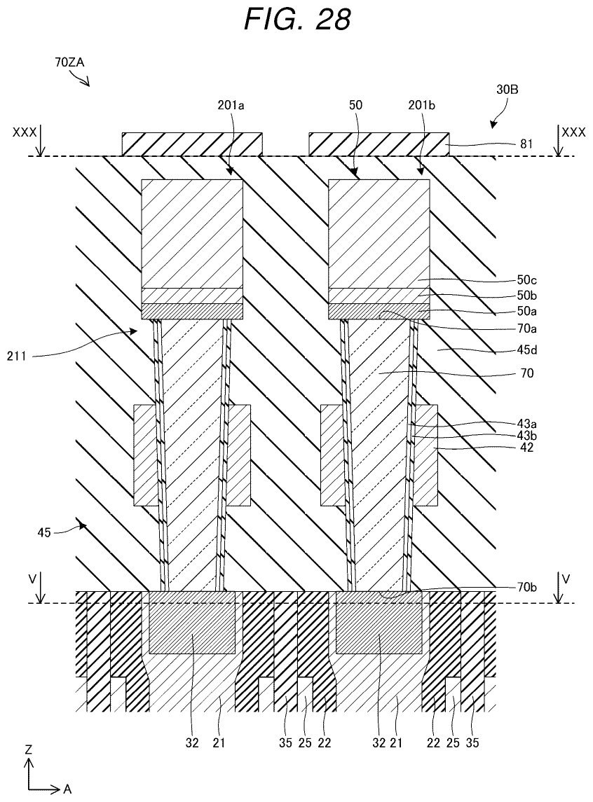

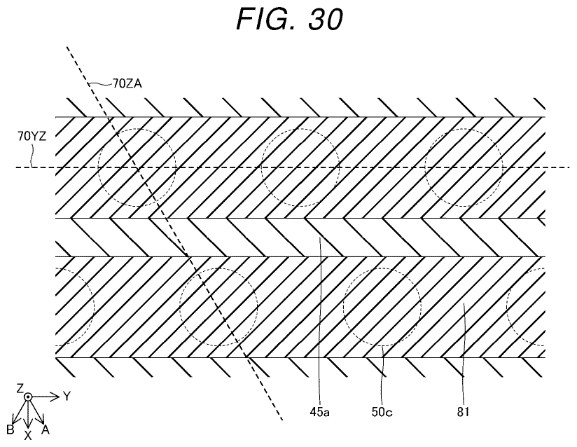

Next, as shown in FIGS. 28 to 30, a plurality of mask layers 81 are formed by performing film formation, resist coating, exposure, development and stripping on the upper surface of the insulating film 45d by lithography. The plurality of mask layers 81 are repeatedly disposed in the X-axis positive direction. Each mask layer 81 extends in the Y-axis positive direction. When the mask layer 81 is viewed from the top, the mask layer 81 and the metal film 50c overlap each other.

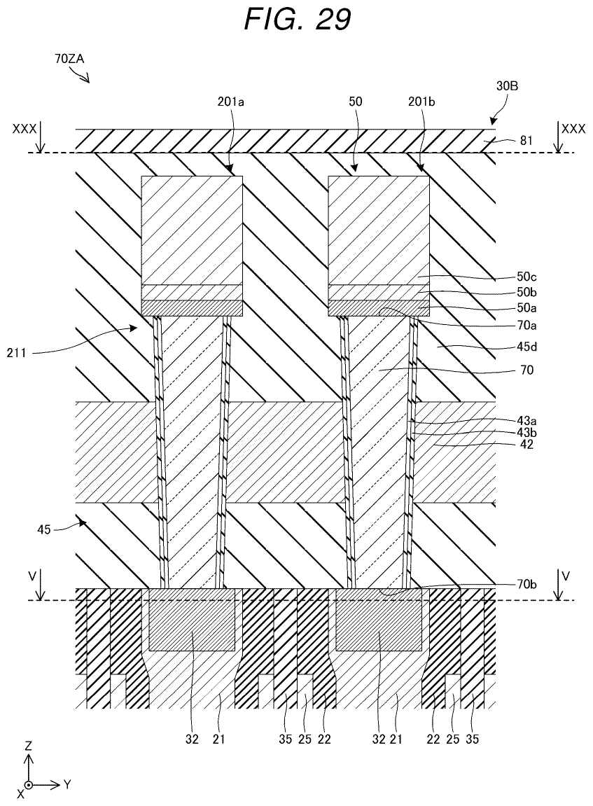

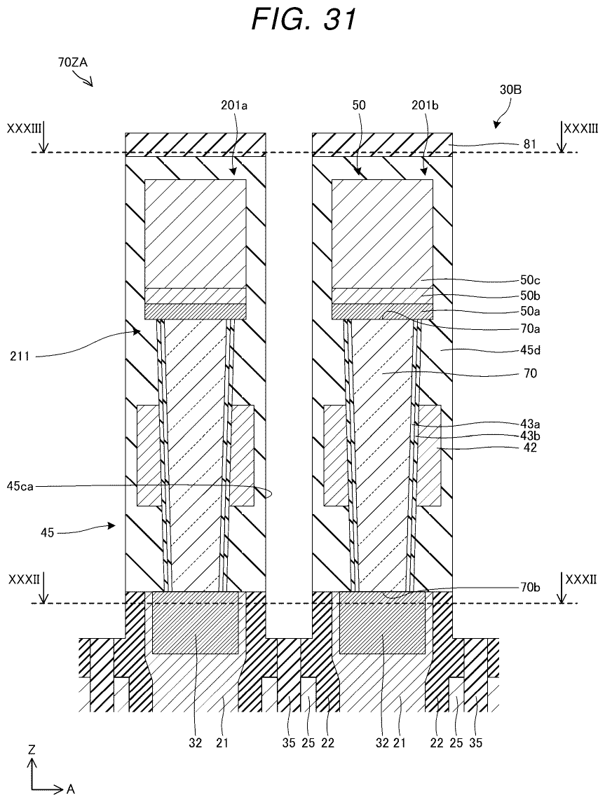

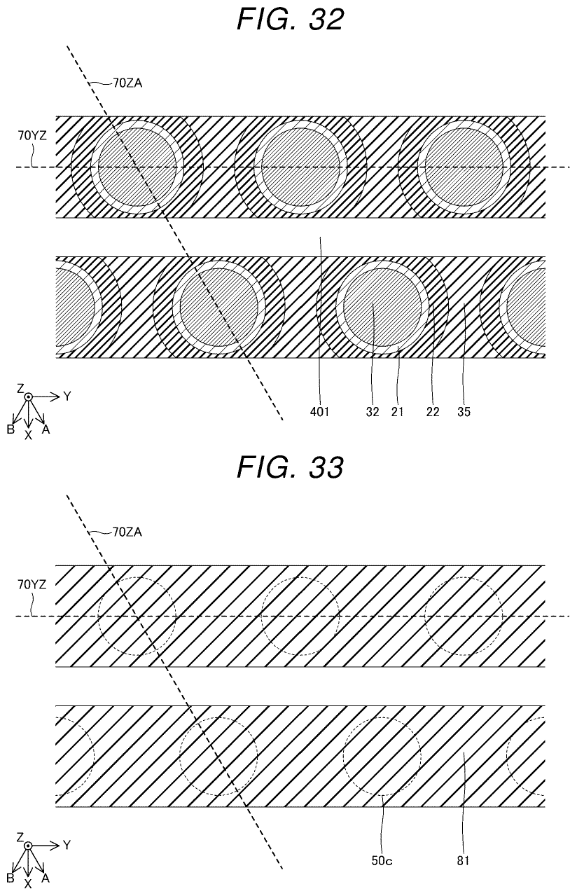

Next, as shown in FIGS. 31 to 33, the groove section 45ca is formed by reactive ion etching, and then, cleaning is performed. The groove section 45ca extends substantially parallel to the XY plane, and divides the insulating film 45d. In the vicinity of the bottom of the groove section 45ca, the insulating layer 35 and the insulating film 22 are exposed. The sidewall of the groove section 45ca is formed to be smooth along the outer contour of the mask layer 81 when viewed from the top. The cross-section 70YZ in the semiconductor device 30B is the same as a cross-section 70YZ in the semiconductor device 30 shown in FIG. 29.

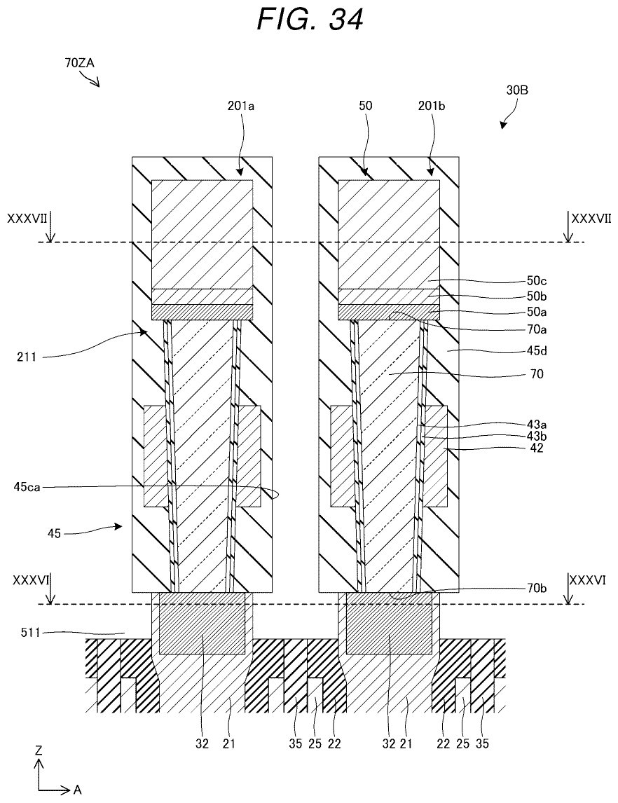

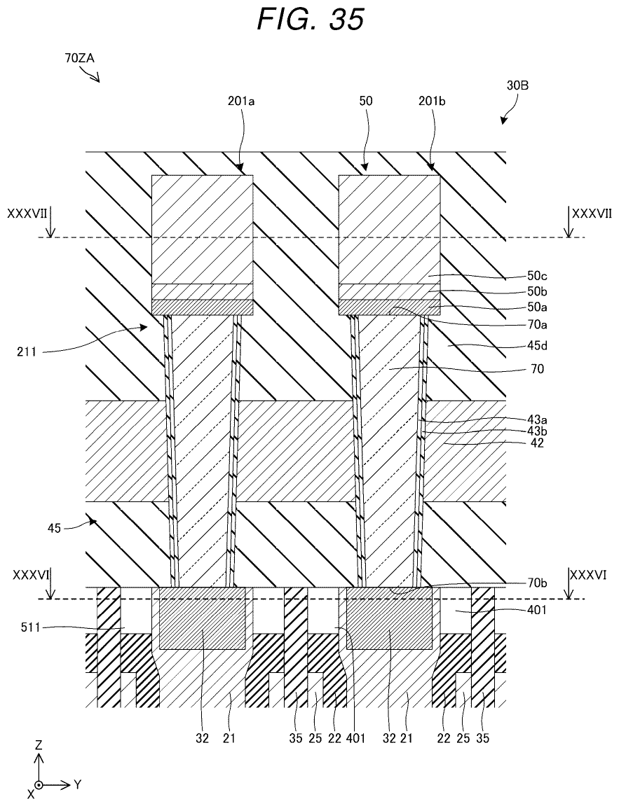

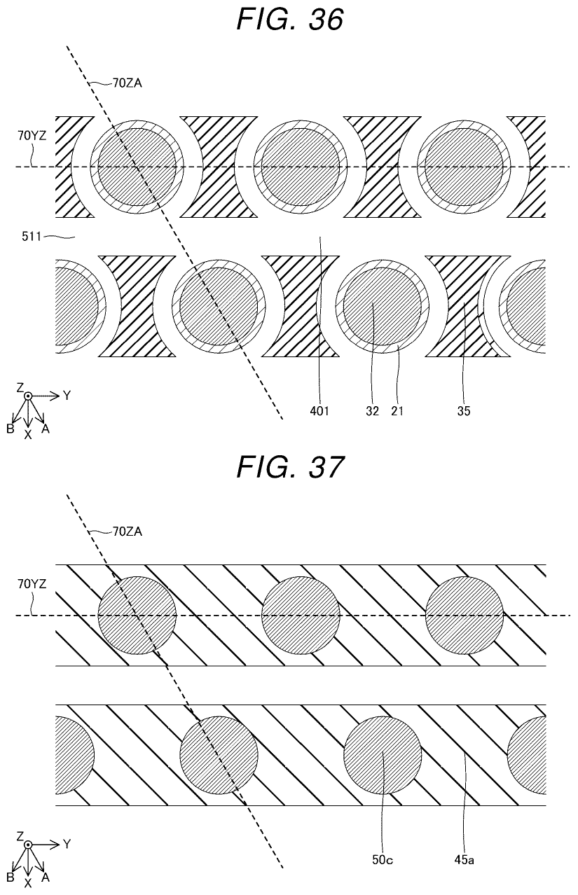

Next, as shown in FIGS. 34 to 37, a part of the insulating film 22 is removed by, for example, wet etching. By this fact, at the layer 511, the conductor 21 is exposed to the cavity section 401. The cavity section 401 surrounds the conductor 21.

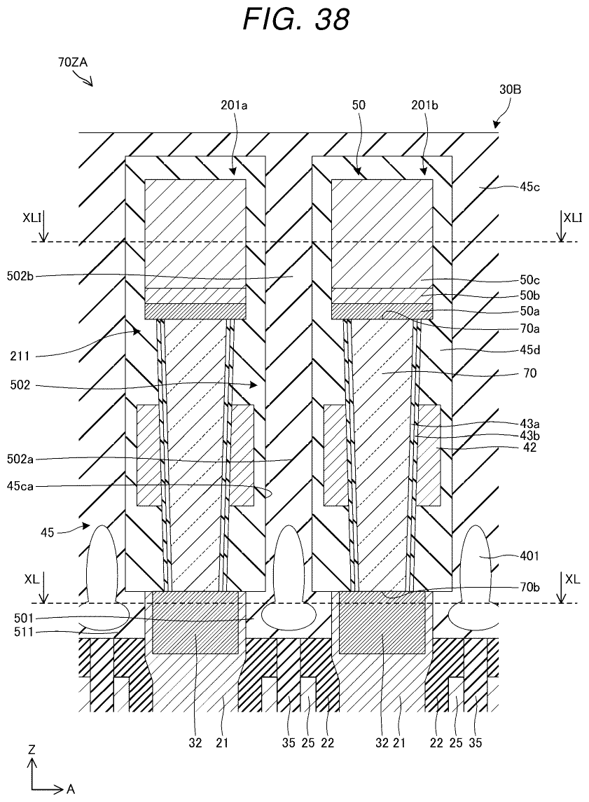

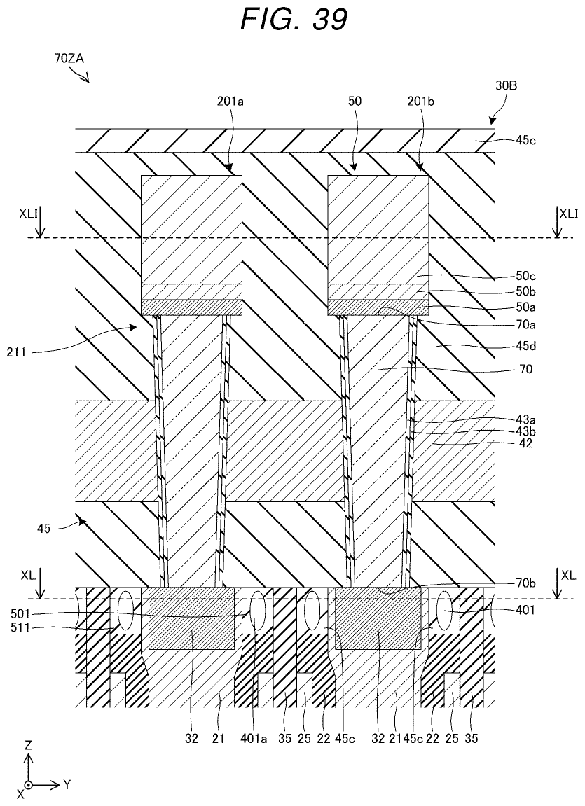

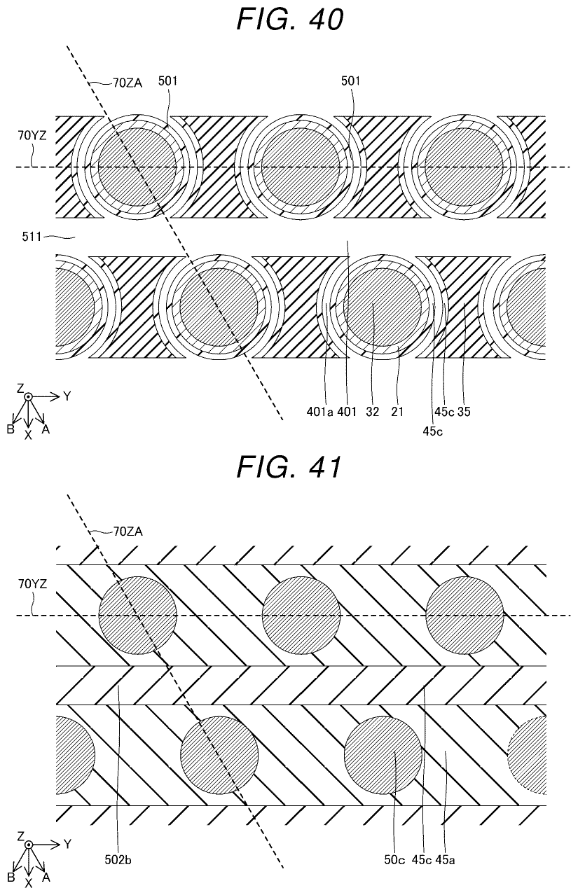

Next, as shown in FIGS. 38 to 41, the insulating film 45c is formed by, for example, atomic layer deposition. The degree of ease with which the insulating film 45c can be embedded, is the same as the degree of ease with which the insulating film 45c can be embedded in the case shown in FIG. 21.

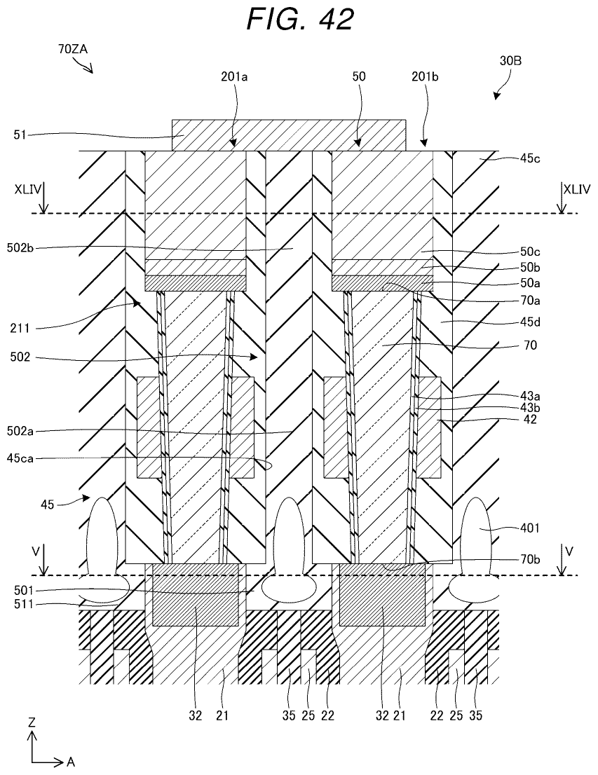

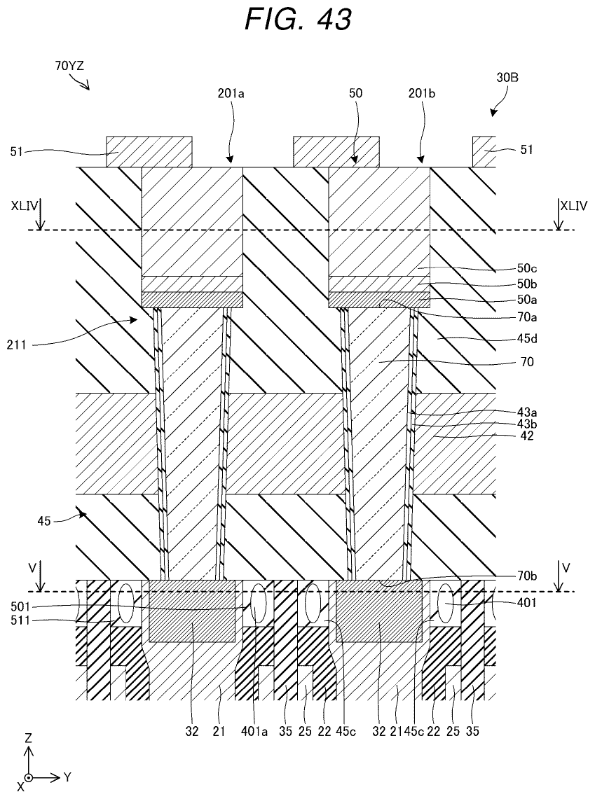

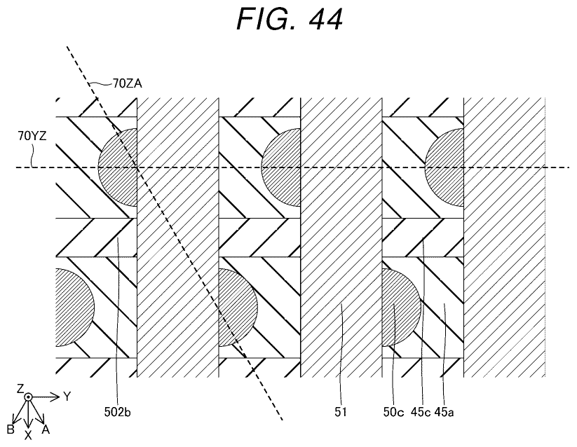

Next, as shown in FIGS. 42 to 44, by removing respective upper parts of the insulating films 45c and 45d by chemical mechanical polishing, the upper surfaces of the insulating films 45c and 45d and the metal film 50c are exposed, and the locations of the upper surfaces of the insulating films 45c and 45d and the metal film 50c in the upward and downward direction are flush with each other. On a surface smoothed in this manner, the conductive layer 51 that extends in the X-axis positive direction and comes into contact with the metal film 50c is formed.

### Second Embodiment

A semiconductor device 30C according to a second embodiment will be described hereunder. In the second and subsequent embodiments, description of components common to the first embodiment will be omitted, and only differences will be described. In particular, the same working effects resulting from the same configurations will not be mentioned in each embodiment.

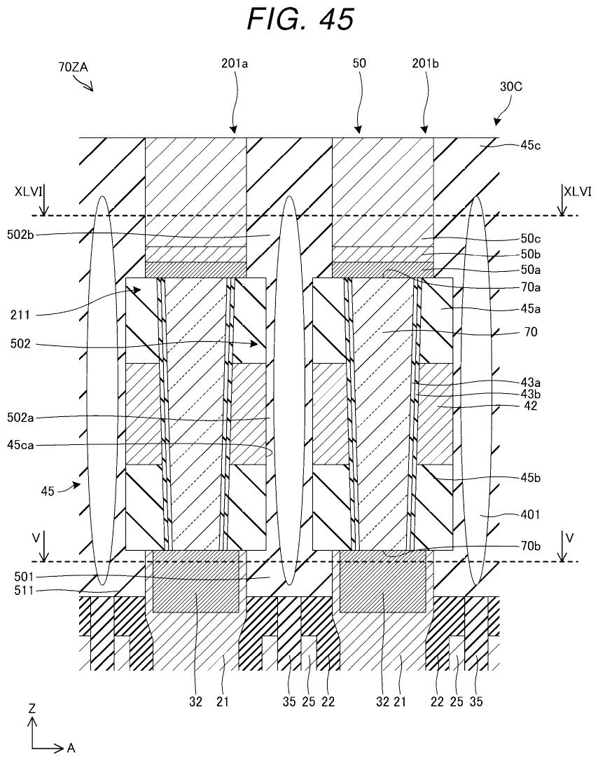

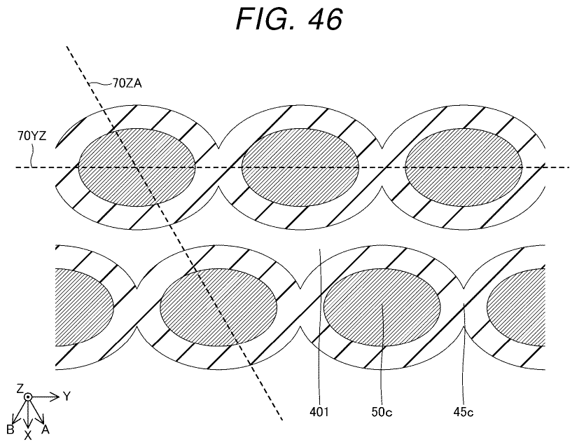

FIG. 45 is a detailed cross-sectional view of the semiconductor device 30C as viewed in the cross-section 70ZA parallel to the ZA plane and included in the oxide semiconductor layer 70. FIG. 46 is a cross-sectional view taken along a line XLVI-XLVI shown in FIG. 45.

The cross-section 70YZ in the semiconductor device 30C is the same as the cross-section 70YZ in the semiconductor device 30 shown in FIG. 4. A cross-section of the semiconductor device 30C taken along a line V-V in FIG. 46 is the same as the cross-section of the semiconductor device 30 taken along the line V-V in FIG. 5.

As shown in FIGS. 4, 5, 45 and 46, the semiconductor device 30C according to the second embodiment differs from the semiconductor device 30 according to the first embodiment in that the cavity section 401 is disposed between two column sets 211 that are adjacent to each other in the A-axis positive direction or the B-axis positive direction.

The cavity section 401 in the semiconductor device 30C is formed, for example, by reducing the degree of ease with which the insulating film 45c can be embedded, more than when manufacturing the semiconductor device 30 shown in FIGS. 4 and 5.

In the semiconductor device 30C, the cavity section 401 capable of efficiently circulating gas such as oxygen is provided from the vicinity of the lower electrode 32 to the vicinity of the metal oxide layer 50a.

By such a configuration, for example, when the semiconductor device 30C is heated under an oxygen atmosphere, oxygen may be effectively supplied to the metal oxide layer 50a and the lower electrode 32 through the cavity section 401. By this fact, it is possible to shorten a time required to supply oxygen to the metal oxide layer 50a and the lower electrode 32.

In addition, since the amount of oxygen supplied to the metal oxide layer 50a and the lower electrode 32 may be made uniform, the carrier concentrations in the metal oxide layer 50a and the lower electrode 32 may be made substantially the same, and thus, the electrical characteristics of the metal oxide layer 50a and the lower electrode 32 may be made substantially the same. By this fact, current may flow substantially symmetrically when current is caused to flow from the lower electrode 32 to the metal oxide layer 50a and when current is caused to flow from the metal oxide layer 50a to the lower electrode 32.

### Third Embodiment

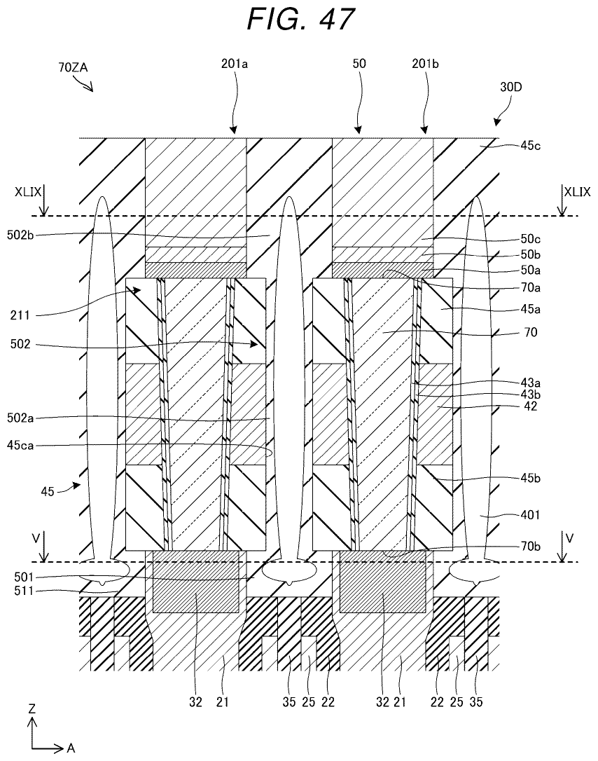

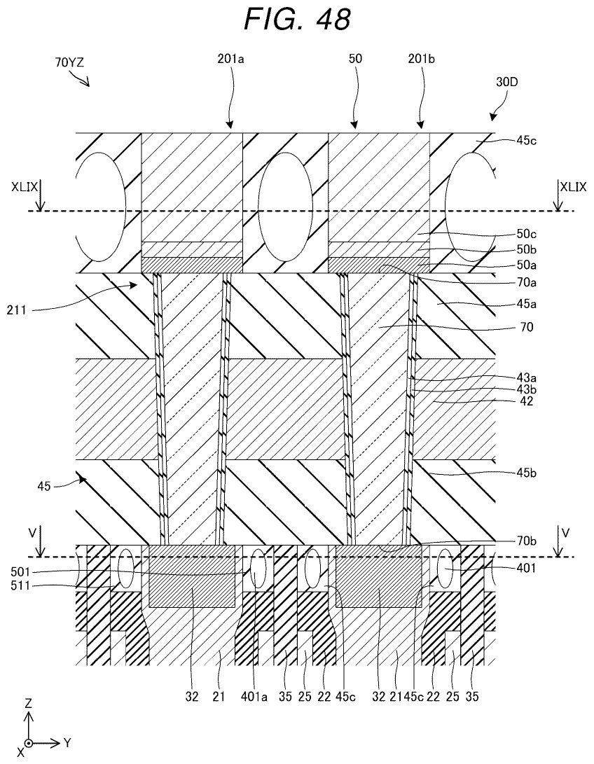

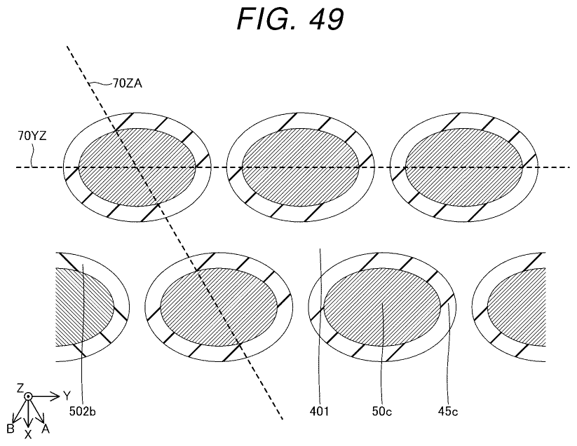

A semiconductor device 30D according to a third embodiment will be described hereunder. FIG. 47 is a detailed cross-sectional view of the semiconductor device 30D as viewed in the cross-section 70ZA parallel to the ZA plane and included in the oxide semiconductor layer 70. FIG. 48 is a detailed cross-sectional view of the semiconductor device 30D as viewed in the cross-section 70YZ parallel to the YZ plane and included in the oxide semiconductor layer 70. FIG. 49 is a cross-sectional view taken along a line XLIX-XLIX shown in FIGS. 47 and 48.

The cross-section of the semiconductor device 30D taken along a line V-V shown in FIGS. 47 and 48 is the same as the cross-section of the semiconductor device 30 taken along the line V-V shown in FIG. 5.

As shown in FIGS. 5 and 47 to 49, the semiconductor device 30D according to the third embodiment differs from the semiconductor device 30C according to the second embodiment in that the cavity section 401 surrounds the side surface of the upper electrode 50.

The semiconductor device 30D is manufactured by, for example, the first manufacturing method. In detail, as shown in FIGS. 19 and 20, when forming the insulating film 45c by atomic layer deposition, the degree of ease with which the insulating film 45c can be embedded, is reduced, and the insulating film 45c is formed to have a small thickness.

Under this process condition, a portion where the insulating film 45c is not disposed, that is, the cavity section 401, is formed between two upper electrodes 50 that are adjacent to each other in the Y-axis positive direction. The cavity section 401 is continuous with the cavity section 401 between two upper electrodes 50 that are adjacent to each other in the A-axis positive direction or the B-axis positive direction. That is to say, the cavity section 401 surrounds the side surface of the upper electrode 50.

By such a configuration, the metal oxide layer 50a may be supplied with oxygen from all directions through the cavity section 401.

### Fourth Embodiment

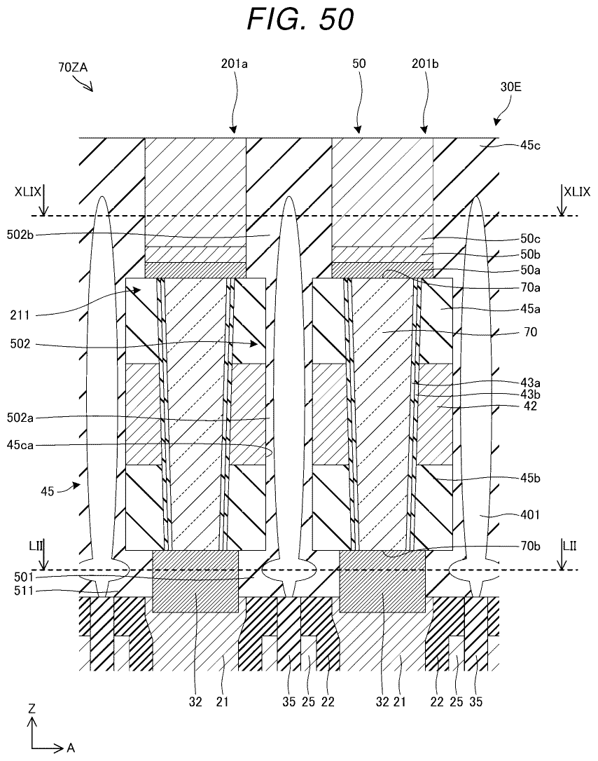

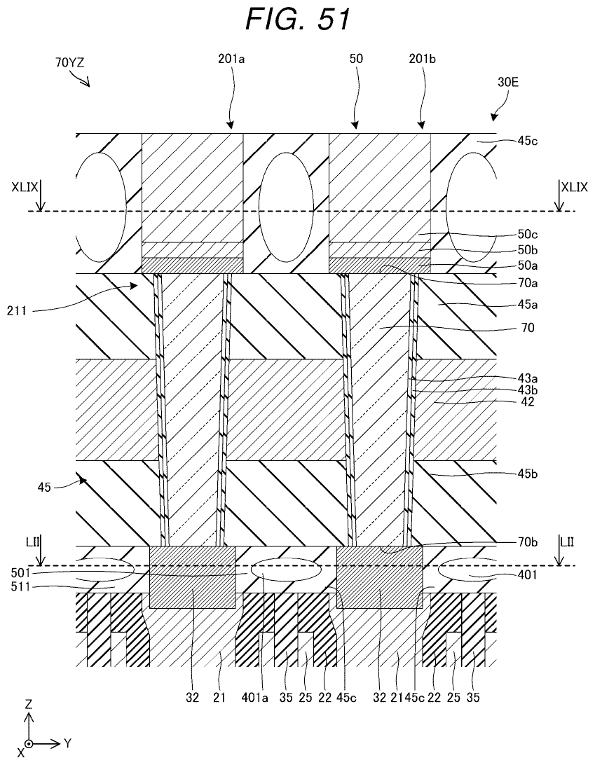

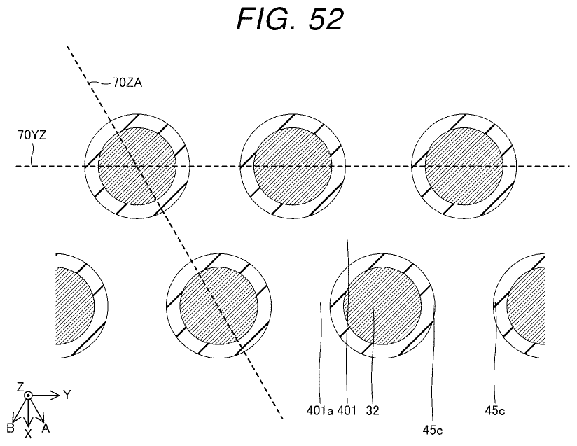

A semiconductor device 30E according to a fourth embodiment will be described. FIG. 50 is a detailed cross-sectional view of the semiconductor device 30E as viewed in the cross-section 70ZA parallel to the ZA plane and included in the oxide semiconductor layer 70. FIG. 51 is a detailed cross-sectional view of the semiconductor device 30E as viewed in the cross-section 70YZ parallel to the YZ plane and included in the oxide semiconductor layer 70. FIG. 52 is a cross-sectional view taken along a line LII-LII shown in FIGS. 50 and 51.

A cross-section of the semiconductor device 30E taken along a line XLIX-XLIX shown in FIGS. 50 and 51 is the same as the cross-section of the semiconductor device 30D taken along a line XLIX-XLIX shown in FIG. 49.

As shown in FIGS. 49 to 52, the semiconductor device 30E according to the fourth embodiment differs from the semiconductor device 30D according to the third embodiment in that the insulating section 501 is in contact with the side surface of the lower electrode 32.

In the semiconductor device 30D, the upper end of the conductor 21 is located lower than the upper end of the lower electrode 32. Furthermore, the locations of the upper end of the conductor 21, the upper end of the insulating film 22 and the upper end of the insulating layer 35 in the upward and downward direction are flush with each other.

An upper part of the side surface of the lower electrode 32 is not covered by the conductor 21. The corresponding part is in contact with the insulating section 501.

The semiconductor device 30E is formed by further removing an upper part of the conductor 21 and an upper part of the insulating layer 35 in the wet etching shown in, for example, FIGS. 17 and 18 or FIGS. 34 and 35.

### Fifth Embodiment

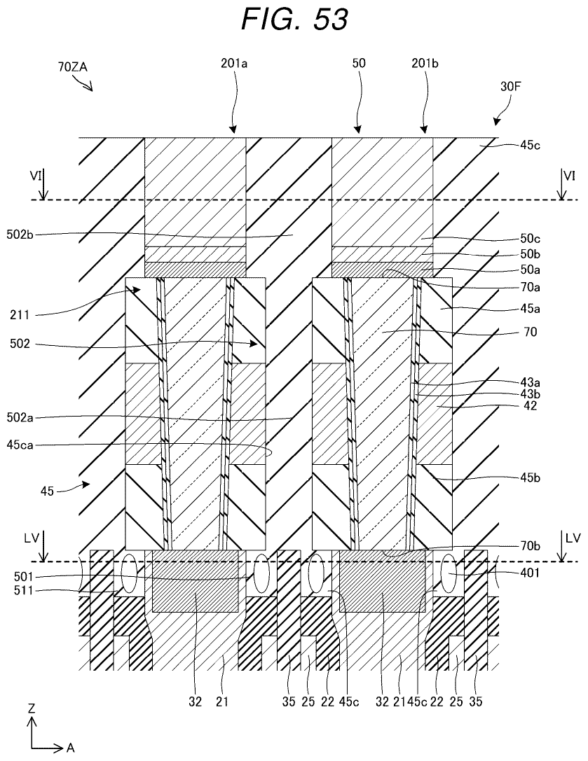

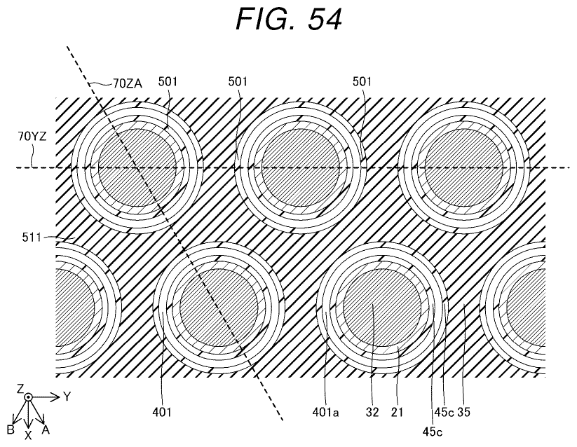

A semiconductor device 30F according to a fifth embodiment will be described. FIG. 53 is a detailed cross-sectional view of the semiconductor device 30F as viewed in the cross-section 70ZA parallel to the ZA plane and included in the oxide semiconductor layer 70. FIG. 54 is a cross-sectional view taken along a line LV-LV shown in FIG. 53.

The cross-section 70YZ in the semiconductor device 30F is the same as the cross-section 70YZ in the semiconductor device 30 shown in FIG. 4. A cross-section of the semiconductor device 30F taken along a line VI-VI shown in FIG. 53 is the same as the cross-section of the semiconductor device 30 taken along the line VI-VI shown in FIG. 6.

As shown in FIGS. 4, 6, 53 and 54, the semiconductor device 30F according to the fifth embodiment differs from the semiconductor device 30 according to the first embodiment in that the entirety of the cavity section 401 is surrounded by the insulating section 501.

The semiconductor device 30F is formed by increasing the degree of ease with which the insulating film 45c can be embedded, when forming the insulating film 45c by atomic layer deposition shown in, for example, FIGS. 19 and 20 or FIGS. 38 and 39.

### Sixth Embodiment

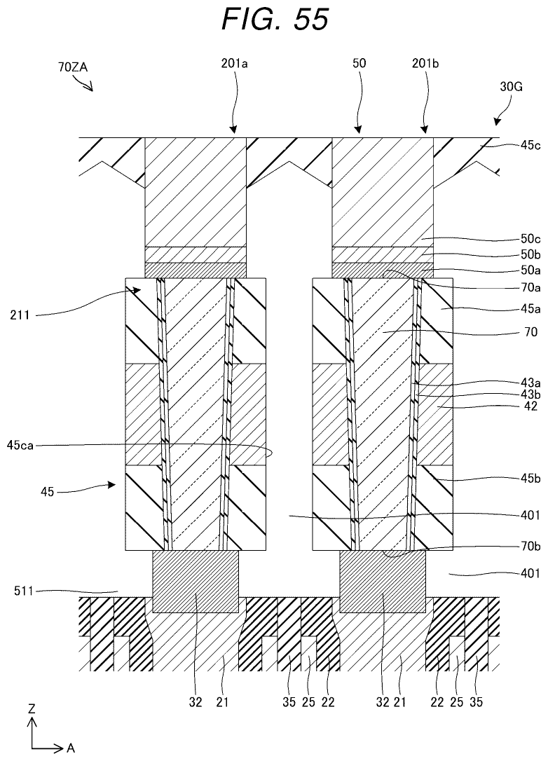

A semiconductor device 30G according to a sixth embodiment will be described. FIG. 55 is a detailed cross-sectional view of the semiconductor device 30G as viewed in the cross-section 70ZA parallel to the ZA plane and included in the oxide semiconductor layer 70.

As shown in FIG. 55, the semiconductor device 30G according to the sixth embodiment differs from the semiconductor device 30E according to the fourth embodiment in that the side surface of the lower electrode 32 is exposed to the cavity section 401.

The semiconductor device 30G is formed by decreasing the degree of ease with which the insulating film 45c can be embedded, when forming the insulating film 45c by atomic layer deposition shown in, for example, FIGS. 19 and 20 or FIGS. 38 and 39. In addition, the semiconductor device 30G may be formed by sputtering instead of atomic layer deposition.

In the semiconductor device 30G, the insulating film 45c is formed between two columnar bodies 201 to form an upper cover. In detail, at the layer 511, the cavity section 401 is formed between two lower electrodes 32. The cavity section 401 is formed between two insulating films 45b, between two conductive layers 42 and between two insulating films 45a. A lower part between two upper electrodes 50 forms the cavity section 401.

In each embodiment, a configuration is described in which the A-axis positive direction is an example of the third direction, but the present disclosure is not limited thereto. The B-axis positive direction may be an example of the third direction.

A semiconductor device includes:
a plurality of oxide semiconductors having respective first ends and respective second ends and extending in a first direction from the second ends to the first ends;
a plurality of first electrodes respectively contacting the first ends of the plurality of oxide semiconductors;
a plurality of second electrodes respectively contacting the second ends of the plurality of oxide semiconductors;
a plurality of gate electrodes extending in a second direction perpendicular to the first direction, and repeatedly disposed in a fourth direction perpendicular to the first direction and the second direction;
a plurality of first insulating films respectively surrounding side surfaces of the plurality of oxide semiconductors; and
a cavity section at least a part of which is disposed between two adjacent second electrodes, in which
the plurality of oxide semiconductors are repeatedly disposed in the second direction and are repeatedly disposed in a third direction intersecting the first direction and the second direction, and
the gate electrode surrounds the plurality of oxide semiconductors between the first ends and the second ends of the plurality of oxide semiconductors disposed in the second direction, with the plurality of first insulating films interposed therebetween.

In one embodiment, a plurality of column sets, each including one of the oxide semiconductors and one of the first electrodes in contact with each other, are arranged side by side in the third direction intersecting the first direction and the second direction, and the cavity section extends between two column sets adjacent to each other in the third direction.

In another embodiment, a plurality of column sets, each including one of the oxide semiconductors and one of the first electrodes in contact with each other, are arranged side by side in the third direction intersecting the first direction and the second direction, and the cavity section extends between two adjacent second electrodes and between two column sets adjacent to each other in the third direction.

Embodiments of the present disclosure have been described above with reference to specific examples. However, the present disclosure is not limited to these specific examples. Any design modifications to these specific examples made by a person skilled in the art are also included within the scope of the present disclosure as long as they incorporate the features of the present disclosure. The elements, arrangement, condition, shape, and the like of each of the above-described specific examples are not limited to those illustrated herein, and may be modified as appropriate. The combination of the elements of each of the above-described specific examples may be modified as appropriate, provided no technical contradictions arise.

While certain embodiments have been described, these embodiments have been presented by way of example only, and are not intended to limit the scope of the disclosure. Indeed, the novel embodiments described herein may be embodied in a variety of other forms; furthermore, various omissions, substitutions, and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a plurality of oxide semiconductors having respective first ends and respective second ends and extending in a first direction from the second ends to the first ends;
a plurality of first electrodes respectively contacting the first ends of the plurality of oxide semiconductors;
a plurality of second electrodes respectively contacting the second ends of the plurality of oxide semiconductors;
a gate electrode extending in a second direction intersecting the first direction and surrounding each of the plurality of oxide semiconductors that are arranged in the second direction, via a first insulating film between the respective first ends thereof and the respective second ends thereof; and
a cavity section at least a part of which is disposed between two adjacent second electrodes.

2. The semiconductor device according to claim 1, wherein
a plurality of column sets, each including one of the oxide semiconductors and one of the first electrodes in contact with each other, are arranged side by side in a third direction intersecting the first direction and the second direction, and
the cavity section extends between two column sets adjacent to each other in the third direction.

3. The semiconductor device according to claim 1, further comprising:
a second insulating film including a first section that is disposed in a layer including the plurality of second electrodes,
wherein at least a part of the cavity section is surrounded by the first section.

4. The semiconductor device according to claim 3, wherein, between the two second electrodes that are adjacent to each other in the second direction, the cavity section forms a tunnel with the first section as an inner wall.

5. The semiconductor device according to claim 3, wherein
a plurality of column sets, each including one of the oxide semiconductors and one of the first electrodes in contact with each other, are arranged side by side in a third direction intersecting the first direction and the second direction,
the second insulating film further includes a second section that is located between the two column sets adjacent to each other in the third direction and is continuous with the first section, and
the cavity section extends from the first section to the second section.

6. The semiconductor device according to claim 5, wherein the cavity section is disposed between the two column sets adjacent to each other in the third direction.

7. The semiconductor device according to claim 6, wherein
each of the first electrodes has a columnar shape that extends from the first end of the respective oxide semiconductor in the first direction, and
the cavity section surrounds a side surface of one of the first electrodes.

8. The semiconductor device according to claim 1, wherein
each of the second electrodes has a columnar shape that extends from the second end of the respective oxide semiconductor in a direction opposite to the first direction, and
the cavity section surrounds a side surface of one of the second electrodes.

9. The semiconductor device according to claim 1, wherein
each of the second electrodes has a columnar shape that extends from the second end of the respective oxide semiconductor in a direction opposite to the first direction, and
a side surface of one of the second electrodes is exposed to the cavity section.

10. The semiconductor device according to claim 1, further comprising:
a second insulating film including a first section that is disposed in a layer including the plurality of second electrodes, wherein at least a part of the cavity section is surrounded by the first section,
each of the second electrodes has a columnar shape that extends from the second end of the respective oxide semiconductor in a direction opposite to the first direction, and
the first section is in contact with side surfaces of the second electrodes.

11. The semiconductor device according to claim 1, wherein the oxide semiconductor includes at least one of indium, gallium, aluminum, zinc, tin, titanium, tungsten and molybdenum, and oxygen.

12. A semiconductor memory device comprising:
the semiconductor device according to claim 1;
a first capacitor electrode connected to one of the second electrodes;
a second capacitor electrode facing the first capacitor electrode; and
a dielectric film disposed between the first capacitor electrode and the second capacitor electrode.

13. The semiconductor memory device according to claim 12, wherein
the first capacitor electrode is disposed under the second electrode to which the first capacitor electrode is connected, and
an upper end of the second capacitor electrode is located below an upper end of the second electrode to which the first capacitor electrode is connected.

14. A semiconductor device comprising:
first and second oxide semiconductors, each having a first end and a second end, and extending in a first direction;
first and second bottom electrodes respectively contacting the first ends of the first and second oxide semiconductors;
first and second top electrodes respectively contacting the second ends of the first and second oxide semiconductors;
a first gate insulating film surrounding the first oxide semiconductor between the first and second ends of the first oxide semiconductor;
a second gate insulating film surrounding the second oxide semiconductor between the first and second ends of the second oxide semiconductor;
a gate electrode extending in a second direction intersecting the first direction and surrounding the first and second gate insulating films; and
at least one cavity section disposed between the first and second bottom electrodes.

15. The semiconductor device according to claim 14, wherein the at least one cavity section includes a first cavity section that surrounds the first bottom electrode and a second cavity section that surrounds the second bottom electrode.

16. The semiconductor device according to claim 15, further comprising:
a third bottom electrode;
a third top electrode aligned with the third bottom electrode in the first direction;
a third oxide semiconductor extending in the first direction between the third bottom electrode and the third top electrode;
a third cavity section between the first bottom electrode and the third bottom electrode in a third direction that intersects the first direction and the second direction; and
a fourth cavity section that is continuous with the third cavity section and is between the first oxide semiconductor and the third oxide semiconductor in the third direction.

17. The semiconductor device according to claim 16, further comprising:
a fifth cavity section that is continuous with the third and fourth cavity sections and is between the first oxide semiconductor and the third oxide semiconductor in the third direction.

18. The semiconductor device according to claim 17, wherein the third direction is perpendicular to the first direction but is not perpendicular to the second direction.

19. The semiconductor device according to claim 14, wherein side surfaces of the first and second bottom electrodes are exposed to the at least one cavity section.

20. A semiconductor memory device comprising:
the semiconductor device according to claim 14;
a first inner capacitor electrode extending in the first direction and connected to the first bottom electrode;
a second inner capacitor electrode extending in the first direction and connected to the second bottom electrode;
a first outer capacitor electrode extending in the first direction and facing the first inner capacitor electrode;
a second outer capacitor electrode extending in the first direction and facing the second inner capacitor electrode;
a first dielectric film extending in the first direction and disposed between the first inner capacitor electrode and the first outer capacitor electrode; and
a second dielectric film extending in the first direction and disposed between the second inner capacitor electrode and the second outer capacitor electrode.
